(19) United States
(12) Patent Application Publication
(10) Pub. No.: US 2022/0223680 A1
(43) Pub. Date: Jul. 14, 2022

(54) MULTILAYER STRUCTURE AND SEMICONDUCTOR DEVICE

(71) Applicant: FLOSFIA INC., Kyoto (JP)

(72) Inventors: Takayoshi OSHIMA, Kyoto (JP); Tatsuya TORIYAMA, Kyoto (JP)

(21) Appl. No.: 17/708,734

(22) Filed: Mar. 30, 2022

Related U.S. Application Data
(63) Continuation-in-part of application No. PCT/JP2020/036990, filed on Sep. 29, 2020.

(30) Foreign Application Priority Data
Sep. 30, 2019 (JP) 2019-179861
Sep. 30, 2019 (JP) 2019-179862
Sep. 30, 2019 (JP) 2019-179863

(51) Int. Cl. H01L 29/04; H01L 29/12; H01L 21/02; C30B 29/16; C30B 25/18; H01L 29/49

(52) U.S. Cl. CPC H01L 29/04; H01L 29/12; H01L 29/4925; C30B 29/16; C30B 25/18; H01L 21/0242

(57) ABSTRACT

Provided is a laminated structure that has a crystalline film having a large area, which is useful for a semiconductor device, etc., and having a good film thickness distribution in which the film thickness is 30 μm or less, and that has excellent heat dissipation. In a laminated structure in which a crystal film containing a crystalline metal oxide as a main component is laminated on a support directly or with another layer therebetween, the support has a thermal conductivity of 100 W/m·K or more at room temperature, and the crystal film has a corundum structure. Furthermore, the film thickness of the crystal film is 1 μm to 30 μm, the area of the crystal film is 15 cm² or more, the distribution of the film thickness in the area is in the range of ±10% or less.

### CROSS REFERENCE TO RELATED APPLICATION

This application is a continuation-in-part application of International Patent Application No. PCT/JP2020/036990 (Filed on Sep. 9, 2020), which claims the benefit of priority from Japanese Patent Application Nos. 2019-179861 (filed on Sep. 30, 2019), 2019-179862 (filed on Sep. 30, 2019) and 2019-179863 (filed on Sep. 30, 2019).

The entire contents of the above applications, which the present application is based on, are incorporated herein by reference.

### 1. FIELD OF THE INVENTION

The present disclosure relates to a multilayer structure that is useful for semiconductor devices, a semiconductor device, a semiconductor system, and a method of producing a multilayer structure.

### 2. DESCRIPTION OF THE RELATED ART

A semiconductor device using gallium oxide (Ga₂O₃) with a wide band gap is drawing attention as a next-generation switching element that can achieve high withstand voltage, low loss, and high heat resistance, and is expected to be applied to power semiconductor devices such as an inverter. Moreover, it is also expected that this semiconductor device finds wide application as light-receiving or emitting devices such as an LED and a sensor due to a wide band gap thereof. According to NPL 1, among gallium oxides, α-Ga₂O₃ having a corundum structure and so forth, in particular, make band gap control possible by mixing thereinto indium or aluminum or a combination of indium and aluminum and form a very appealing family material as InAlGaO-based semiconductors. Here, InAlGaO-based semiconductors indicate InₓAl_{y}Ga_{z}O₃ (0≤X≤2, 0≤Y≤2, 0≤Z≤2, X+Y+Z=1.5 to 2.5) and may be regarded as a family of materials including gallium oxide.

However, since the most stable phase of gallium oxide is a gallia structure, it is difficult to form a crystal film having a corundum structure which is a metastable phase unless a special film formation method is used, and crystal growth conditions are often limited to heteroepitaxial growth or the like, for example, which tends to make the dislocation density high. Moreover, there are still many problems not only in a crystal film having a corundum structure, but also in, for example, improvements in film formation rate and crystal quality, prevention of cracks and abnormal growth, twin prevention, and a fracture in a substrate due to warpage. Under these circumstances, several studies of film formation of a crystalline semiconductor having a corundum structure are being conducted.

### SUMMARY OF THE INVENTION

According to an example of the present disclosure, there is provided a multilayer structure including, a crystal film containing a crystalline metal oxide as a major component and arranged directly on a support or arranged on the support via another layer, the support having a thermal conductivity of 100 W/m·K or higher at ambient temperature, the crystal film having a corundum structure, a film thickness of in a range of 1 μm to 30 μm, and an area of 15 cm² or more, a distribution of the film thickness in the area falling within a range of ±10%.

According to an example of the present disclosure, there is provided a multilayer structure including, a crystal film containing a crystalline metal oxide as a major component and arranged directly on a support or arranged on the support via another layer, the support having a thermal conductivity of 100 W/m·K or higher at ambient temperature, the crystal film having a β gallia structure, a principal plane of the crystal film being a (001) plane or a (100) plane, the crystal film having a film thickness of in a range of 1 μm to 30 μm and an area of 15 cm² or more, a distribution of the film thickness in the area falling within a range of ±10%.

According to an example of the present disclosure, there is provided a method of producing a multilayer structure including, forming a crystal growth layer on a crystal growth substrate by crystal growth including lateral crystal growth; adhering a support having a thermal conductivity of 100 W/m·K or higher at ambient temperature to the crystal growth layer; and separating the crystal growth substrate.

Thus, in a multilayer structure of the present disclosure, a multilayer structure of the present disclosure may have a large-area crystal film having a favorable film thickness distribution and a film thickness of 30 μm or less, achieve good heat dissipation, and be useful for semiconductor devices and so forth.

### BRIEF DESCRIPTION OF THE DRAWINGS

FIG. 1 is a schematic diagram explaining a part of a suitable process of producing a multilayer structure of the present disclosure;

FIG. 2 is a schematic diagram explaining a part of the suitable process of producing the multilayer structure of the present disclosure;

FIG. 3 is a schematic diagram explaining a part of the suitable process of producing the multilayer structure of the present disclosure;

FIG. 4 is a schematic diagram explaining a part of the suitable process of producing the multilayer structure of the present disclosure;

FIG. 5 is a schematic diagram explaining a part of the suitable process of producing the multilayer structure of the present disclosure;

FIG. 6 is a schematic diagram explaining a part of the suitable process of producing the multilayer structure of the present disclosure;

FIG. 7 is a schematic diagram explaining a part of the suitable process of producing the multilayer structure of the present disclosure;

FIG. 8 is a schematic diagram explaining a part of the suitable process of producing the multilayer structure of the present disclosure;

FIG. 9 is a schematic diagram explaining a part of the suitable process of producing the multilayer structure of the present disclosure;

FIG. 10 is a schematic diagram explaining a part of the suitable process of producing the multilayer structure of the present disclosure;

FIG. 11 is a diagram explaining a halide vapor phase epitaxy (HVPE) system that is suitably used in the present disclosure;

FIG. 12 is a schematic diagram showing one form of an uneven portion formed on a front surface of a substrate that is suitably used in the present disclosure;

FIG. 13 is a schematic diagram showing one form of an uneven portion formed on a front surface of a substrate that is suitably used in the present disclosure;

FIG. 14 is a schematic diagram showing one form of an uneven portion formed on a front surface of a substrate that is suitably used in the present disclosure;

FIG. 15 is a schematic diagram showing one form of an uneven portion formed on a front surface of a substrate that is suitably used in the present disclosure;

FIG. 16 is a schematic diagram showing one form of an uneven portion formed on a front surface of a substrate that is suitably used in the present disclosure;

FIG. 17 is a schematic diagram showing one form of an uneven portion formed on a front surface of a substrate that is suitably used in the present disclosure;

FIG. 18 is a schematic diagram cross-sectionally showing the relationship between an uneven portion and a crystal growth layer which are formed on a front surface of a substrate that is suitably used in the present disclosure;

FIG. 19 is a schematic diagram cross-sectionally showing the relationship between an uneven portion, a buffer layer, and a crystal growth layer which are formed on a front surface of a substrate that is suitably used in the present disclosure;

FIG. 20 is a schematic diagram showing one form of an uneven portion formed on a front surface of a substrate that is suitably used in the present disclosure;

FIG. 21 is a diagram schematically showing a front surface of the uneven portion formed on the front surface of the substrate that is suitably used in the present disclosure;

FIG. 22 is a schematic diagram showing one form of an uneven portion formed on a front surface of a substrate that is suitably used in the present disclosure;

FIG. 23 is a diagram schematically showing a front surface of the uneven portion formed on the front surface of the substrate that is suitably used in the present disclosure;

FIG. 24 is a schematic diagram showing one form of an uneven portion formed on a front surface of a substrate that is suitably used in the present disclosure; (a) being a schematic perspective view of the uneven portion and (b) being a schematic surface view of the uneven portion;

FIG. 25 is a schematic diagram showing one form of an uneven portion formed on a front surface of a substrate that is suitably used in the present disclosure; (a) being a schematic perspective view of the uneven portion and (b) being a schematic surface view of the uneven portion;

FIG. 26 is a diagram explaining mist CVD equipment that is suitably used in the present disclosure;

FIG. 27 is a diagram schematically showing one suitable example of a power supply system;

FIG. 28 is a diagram schematically showing one suitable example of a system unit;

FIG. 29 is a diagram schematically showing one suitable example of a power supply circuit diagram of a power supply device;

FIG. 30 is a diagram schematically showing one suitable example of a semiconductor device bonded to a leadframe, a circuit board, or a heat dissipation substrate; and

FIG. 31 is a diagram schematically showing one suitable example of a power card.

### DETAILED DESCRIPTION

Embodiments of the present disclosure will be described below with reference to the accompanying drawings. In the following description, the same parts and components are designated by the same reference numerals. The present embodiment includes, for example, the following disclosures.

### [Structure 1]

A multilayer structure including: a crystal film containing a crystalline metal oxide as a major component and arranged directly on a support or arranged on the support via another layer, the support having a thermal conductivity of 100 W/m·K or higher at ambient temperature, the crystal film having a corundum structure, a film thickness of in a range of 1 μm to 30 μm, and an area of 15 cm² or more, a distribution of the film thickness in the area falling within a range of ±10%.

### [Structure 2]

A multilayer structure including: a crystal film containing a crystalline metal oxide as a major component and arranged directly on a support or arranged on the support via another layer, the support having a thermal conductivity of 100 W/m·K or higher at ambient temperature, the crystal film having a β gallia structure, a principal plane of the crystal film being a (001) plane or a (100) plane, the crystal film having a film thickness of in a range of 1 μm to 30 μm and an area of 15 cm² or more, a distribution of the film thickness in the area falling within a range of ±10%.

### [Structure 3]

The multilayer structure according to [Structure 1] or [Structure 2], wherein the crystalline metal oxide contains at least gallium.

### [Structure 4]

The multilayer structure according to any one of [Structure 1] to [Structure 3], wherein the crystal film is a semiconductor film.

### [Structure 5]

The multilayer structure according to [Structure 1], wherein a principal plane of the crystal film is an r plane or an S plane.

### [Structure 6]

The multilayer structure according to any one of [Structure 1] to [Structure 5], wherein the distribution of the film thickness in the area falls within a range of ±5% or less.

### [Structure 7]

The multilayer structure according to any one of [Structure 1] to [Structure 6], wherein a dislocation density of the crystal film is 1.0×10⁶/cm² or less.

### [Structure 8]

The multilayer structure according to [Structure 2], wherein a dislocation density of the crystal film is 1.0×10³/cm² or less.

### [Structure 9]

The multilayer structure according to any one of [Structure 1] to [Structure 8], wherein the area of the crystal film is 100 cm² or more.

### [Structure 10]

The multilayer structure according to any one of [Structure 1] to [Structure 9], wherein the support contains silicon.

### [Structure 11]

The multilayer structure according to any one of [Structure 1] to [Structure 10], wherein the support is a SiC substrate or a Si substrate.

### [Structure 12]

The multilayer structure according to any one of [Structure 1] to [Structure 11], wherein the support is a 4-inch substrate, a 6-inch substrate, an 8-inch substrate, or a 12-inch substrate.

### [Structure 13]

A semiconductor device including at least: an electrode; and a semiconductor layer, wherein the semiconductor device includes the multilayer structure according to any one of [Structure 1] to [Structure 12].

### [Structure 14]

The semiconductor device according to [Structure 13], wherein the crystal film of the multilayer structure is a semiconductor film, and wherein the semiconductor film is used as the semiconductor layer.

### [Structure 15]

The semiconductor device according to [Structure 13] or [Structure 14], wherein the semiconductor device is a power device.

### [Structure 16]

A semiconductor system including: a semiconductor device, wherein the semiconductor device is the semiconductor device according to any one of [Structure 13] to [Structure 15].

### [Structure 17]

A method of producing a multilayer structure including: forming a crystal growth layer on a crystal growth substrate by crystal growth including lateral crystal growth; adhering a support having a thermal conductivity of 100 W/m·K or higher at ambient temperature to the crystal growth layer; and separating the crystal growth substrate.

### [Structure 18]

The production method according to [Structure 17], wherein the support contains silicon.

### [Structure 19]

The production method according to [Structure 17] or [Structure 18], wherein the support is a SiC substrate or a Si substrate.

### [Structure 20]

The production method according to any one of [Structure 17] to [Structure 19], wherein an area of the support is 15 cm² or more.

### [Structure 21]

The production method according to any one of [Structure 17] to [Structure 20], wherein an area of the support is 100 cm² or more.

### [Structure 22]

The production method according to any one of [Structure 17] to [Structure 21], wherein the crystal growth layer contains gallium.

### [Structure 23]

The production method according to any one of [Structure 17] to [Structure 22], wherein the crystal growth layer contains a crystalline oxide as a major component.

### [Structure 24]

The production method according to [Structure 23], wherein the crystalline oxide includes Ga₂O₃.

### [Structure 25]

The production method according to any one of [Structure 17] to [Structure 24], wherein the crystal growth substrate has a corundum structure, and wherein a crystal growth surface of the crystal growth substrate is an r plane or an S plane.

### [Structure 26]

The production method according to any one of [Structure 17] to [Structure 24], wherein the crystal growth substrate has a β gallia structure, and wherein a crystal growth surface of the crystal growth substrate is a (100) plane or a (001) plane.

### [Structure 27]

The production method according to any one of [Structure 17] to [Structure 26], wherein the crystal growth is performed by HVPE or mist CVD.

### [Structure 28]

The production method according to any one of [Structure 17] to [Structure 27], wherein the lateral crystal growth is performed using an ELO mask.

### [Structure 29]

The production method according to [Structure 28], wherein the ELO mask has a striped pattern or a dot pattern.

A multilayer structure of the present disclosure is a multilayer structure including a crystal film containing a crystalline metal oxide as a major component and arranged directly on a support or arranged on the support with another layer placed between the crystal film and the support, the support having a thermal conductivity of 100 W/m·K or higher at ambient temperature, the crystal film having a corundum structure, a film thickness of 1 to 30 μm, and an area of 15 cm² or more, a distribution of the film thickness in the area falling within a range of ±10% or less. It is to be noted that a “thermal conductivity” refers to a thermal conductivity (W/m·K) at ambient temperature. Moreover, the “distribution of the film thickness” refers to a difference between a maximum film thickness and a minimum film thickness with respect to the average film thickness of the crystal film; for the sake of convenience, the distribution of the film thickness can be calculated by conventional means using a spatial frequency or can be calculated using film thicknesses obtained at any five or more points on a film surface. As one of the embodiments of the present disclosure, the distribution of the film thickness is preferably ±5% or less because this makes it possible to achieve better semiconductor characteristics. The area of the crystal film is not limited to a particular area as long as the area is 15 cm² or more; as one of the embodiments of the present disclosure, the area of the crystal film is preferably 100 cm² or more because this makes it possible to use the crystal film in semiconductor devices and so forth in a more industrially advantageous manner. Furthermore, in the present disclosure, it is preferable that the dislocation density of the crystal film is 1.0×10⁶/cm² or less. A “dislocation density” here refers to a dislocation density that is determined from the number of dislocations per unit area which are observed in a planar or cross-sectional TEM image. The crystalline metal oxide is not limited to a particular crystalline metal oxide and suitable examples thereof include a metal oxide containing one or two or more types of metal selected from aluminum, gallium, indium, iron, chromium, vanadium, titanium, rhodium, nickel, cobalt, iridium and so forth. In the present disclosure, the crystalline metal oxide preferably contains one or two or more types of elements selected from indium, aluminum, and gallium, more preferably contains at least indium or/and gallium, and most preferably contains at least gallium. A “major component” means that the crystalline metal oxide constitutes preferably 50% or more, more preferably 70% or more, and further preferably 90% or more of all the components of the crystal film in terms of atom ratio and means that the crystalline metal oxide may constitute 100% of all the components of the crystal film in terms of atom ratio. The crystal film may be a conductive film or an insulating film; in the present disclosure, the crystal film is preferably a semiconductor film and may contain dopant or the like. Moreover, it is preferable that the crystal film includes two or more lateral crystal growth layers. A principal plane of the crystal film is not limited to a particular plane; in the present disclosure, a principal plane of the crystal film is preferably an r plane, an S plane, or an m plane and more preferably an r plane or an S plane.

Furthermore, a multilayer structure of the present disclosure is a multilayer structure including a crystal film containing a crystalline metal oxide as a major component and arranged directly on a support or arranged on the support with another layer placed between the crystal film and the support, the support having a thermal conductivity of 100 W/m·K or higher, the crystal film having a β gallia structure, a principal plane of the crystal film being a (001) plane or a (100) plane, the crystal film having a film thickness of 1 to 30 μm and an area of 15 cm² or more, and a distribution of the film thickness in the area falling within a range of ±10% or less. It is to be noted that a “thermal conductivity” refers to a thermal conductivity (W/m·K) at ambient temperature. Moreover, the “distribution of the film thickness” refers to a difference between a maximum film thickness and a minimum film thickness with respect to the average film thickness of the crystal film; for the sake of convenience, the distribution of the film thickness can be calculated by conventional means using a spatial frequency or can be calculated using film thicknesses obtained at any five or more points on a film surface. As one of embodiments of the present disclosure, the distribution of the film thickness is preferably ±5% or less because this makes it possible to achieve better semiconductor characteristics. The area of the crystal film is not limited to a particular area as long as the area is 15 cm² or more; as one of embodiments of the present disclosure, the area of the crystal film is preferably 100 cm² or more because this makes it possible to use the crystal film in semiconductor devices and so forth in a more industrially advantageous manner. Furthermore, in the present disclosure, when the crystal film has a gallia structure, in particular, it is preferable that the dislocation density of the crystal film is 1.0×10³/cm² or less. A “dislocation density” here refers to a dislocation density that is determined from the number of dislocations per unit area which are observed in a planar or cross-sectional TEM image. In the present disclosure, it is preferable that the crystalline metal oxide contains at least gallium. A “major component” means that the crystalline metal oxide constitutes preferably 50% or more, more preferably 70% or more, and further preferably 90% or more of all the components of the crystal film in terms of atom ratio and means that the crystalline metal oxide may constitute 100% of all the components of the crystal film in terms of atom ratio. The crystal film may be a conductive film or an insulating film; in the present disclosure, the crystal film is preferably a semiconductor film and may contain dopant or the like. Moreover, it is preferable that the crystal film includes two or more lateral crystal growth layers.

The multilayer structure can be easily obtained by, for example, forming a crystal growth layer (hereinafter, a crystal growth layer that is obtained on a crystal substrate by crystal growth including lateral crystal growth is also referred to simply as a “first lateral crystal growth layer”) on a crystal growth substrate (hereinafter also referred to simply as a “crystal substrate” or a “substrate”) by crystal growth including lateral crystal growth, adhering a support having a thermal conductivity of 100 W/m·K or higher at ambient temperature to the crystal growth layer, and separating the crystal growth substrate. Such a method of producing a multilayer structure is also included in embodiments of the present disclosure as one of them. “Lateral crystal growth” generally refers to performing crystal growth on a crystal growth substrate in a direction that is not a direction (that is, a crystal growth direction) which is a crystal growth axis of a crystal growth surface; in the present disclosure, crystal growth is preferably performed in a direction which forms an angle of 0.1 to 178° with the crystal growth direction, more preferably performed in a direction which forms an angle of 1 to 175° with the crystal growth direction, and most preferably performed in a direction which forms an angle of 5 to 170° with the crystal growth direction. In the present disclosure, the crystal growth layer (hereinafter also referred to as the “crystal film”) preferably has a corundum structure, and the crystal growth layer also preferably contains gallium and more preferably contains Ga₂O₃. Moreover, in the present disclosure, it is also preferable that the crystal growth layer has a β-gallia structure. In the present disclosure, since a crystal film that is useful for a semiconductor device can be obtained, the crystal film is preferably a semiconductor film and more preferably a wide-band-gap semiconductor film. It is preferable to apply HVPE or CVD such as mist CVD to each crystal growth using a crystal substrate with a front surface on which an uneven portion consisting of depressions or projections is formed. It is to be noted that, on the crystal substrate, a groove may be provided or an ELO mask (hereinafter also referred to simply as a “mask”) from which at least a part of the front surface of the crystal substrate is exposed may be placed and the crystal growth layer can be formed thereon by the crystal growth, including lateral crystal growth.

Hereinafter, one example of a method of forming the crystal growth layer (hereinafter also referred to as the “crystal film”) using HVPE mentioned above will be described.

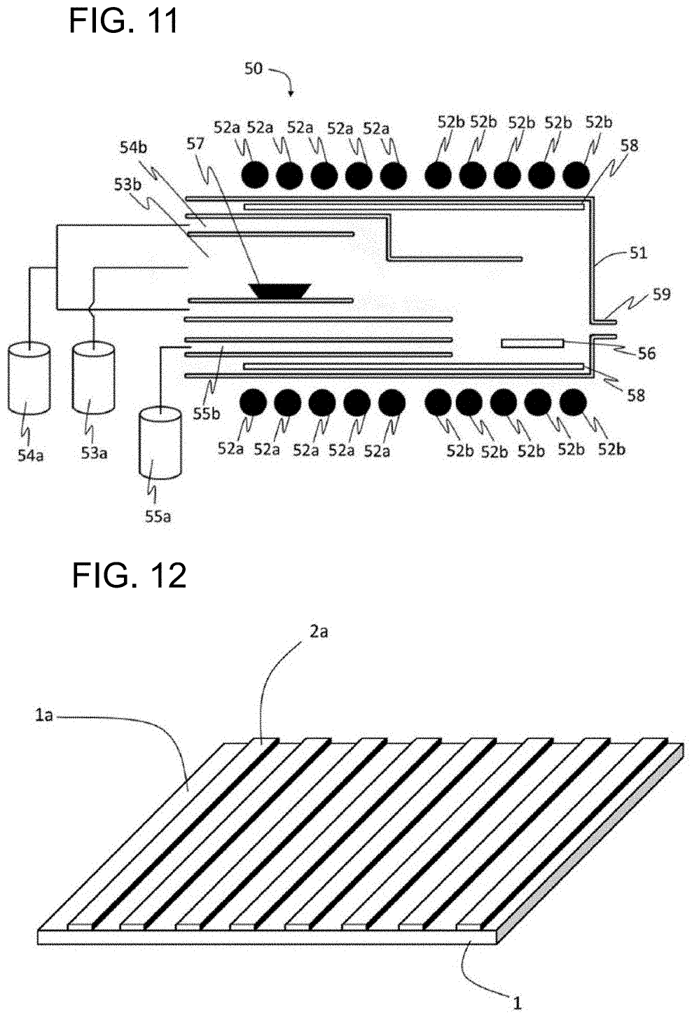

One of embodiments of HVPE mentioned above is as follows: when film formation is performed using, for example, a HVPE system shown in FIG. 11 by gasifying a metal source containing metal to obtain metal-containing source gas and supplying the metal-containing source gas and oxygen-containing source gas to the space above a substrate inside a reaction chamber, a substrate with a front surface on which an uneven portion consisting of depressions or projections is formed is used, reactive gas is supplied to the space above the substrate, and the film formation is performed with the reactive gas being circulated.

### (Metal Source)

The metal source is not limited to a particular metal source as long as the metal source contains metal and can be gasified, and may be elemental metal or a metal compound. Examples of the metal include one or two or more types of metal selected from gallium, aluminum, indium, iron, chromium, vanadium, titanium, rhodium, nickel, cobalt, iridium and so forth. In the present disclosure, the metal is preferably one or two or more types of metal selected from gallium, aluminum, and indium and more preferably gallium, and the metal source is most preferably elemental gallium. Moreover, the metal source may be gas, liquid, or solid; in the present disclosure, when gallium is used as the metal, for example, it is preferable that the metal source is liquid.

A means for the gasification is not limited to a particular means unless it interferes with the object of the present disclosure, and may be a publicly known means. In the present disclosure, it is preferable that the means for the gasification is performed by halogenating the metal source. A halogenating agent that is used in the halogenation is not limited to a particular halogenating agent as long as the halogenating agent can halogenate the metal source, and may be a publicly known halogenating agent. Examples of the halogenating agent include halogens, hydrogen halides or the like. Examples of the halogens include fluorine, chlorine, bromine, iodine or the like. Moreover, examples of the hydrogen halides include hydrogen fluoride, hydrogen chloride, hydrogen bromide, and hydrogen iodide. In the present disclosure, a hydrogen halide is preferably used in the halogenation and hydrogen chloride is more preferably used in the halogenation. In the present disclosure, it is preferable that the gasification is performed by supplying a halogen or hydrogen halide to the metal source as a halogenating agent and making the metal source and the halogen or hydrogen halide react with each other at a temperature equal to or higher than a vaporization temperature of a metal halide to form a metal halide. The halogenation reaction temperature is not limited to a particular temperature; in the present disclosure, when, for example, the metal of the metal source is gallium and the halogenating agent is HCl, the halogenation reaction temperature is preferably 900° C. or lower, more preferably 700° C. or lower, and most preferably 400 to 700° C. The metal-containing source gas is not limited to particular metal-containing source gas as long as the metal-containing source gas is gas containing the metal of the metal source. Examples of the metal-containing source gas include a halide (such as fluoride, chloride, bromide, or iodide) of the metal.

In an embodiment of the present disclosure, after a metal source containing metal is gasified to obtain metal-containing source gas, the metal-containing source gas and the oxygen-containing source gas are supplied to the space above a substrate inside the reaction chamber. Moreover, in an embodiment of the present disclosure, reactive gas is supplied to the space above the substrate. Examples of the oxygen-containing source gas include O₂ gas, CO₂ gas, NO gas, NO₂ gas, N₂O gas, H₂O gas, O₃ gas) or the like. In the present disclosure, the oxygen-containing source gas is preferably one or two or more types of gas selected from a group consisting of O₂, H₂O, and N₂O and more preferably contains O₂. It is to be noted that the oxygen-containing source gas may contain CO₂ as one of embodiments. The reactive gas is generally reactive gas that is different from metal-containing source gas and oxygen-containing source gas and inert gas is not included therein. The reactive gas is not limited to particular reactive gas and examples thereof include etching gas. The etching gas is not limited to particular etching gas unless it interferes with the object of the present disclosure, and may be publicly known etching gas. In the present disclosure, the reactive gas is preferably halogen gas (for example, fluorine gas, chlorine gas, bromine gas, or iodine gas), hydrogen halide gas (for example, hydrofluoric acid gas, hydrochloric acid gas, hydrobromic gas, and hydrogen iodide gas), hydrogen gas, mixed gas of two or more of these gases, or the like, preferably contains hydrogen halide gas, and most preferably contains hydrogen chloride. It is to be noted that the metal-containing source gas, the oxygen-containing source gas, and the reactive gas may contain carrier gas. Examples of the carrier gas include inert gas such as nitrogen and argon. Moreover, the partial pressure of the metal-containing source gas is not limited to a particular partial pressure; in the present disclosure, the partial pressure of the metal-containing source gas is preferably 0.5 Pa to 1 kPa and more preferably 5 Pa to 0.5 kPa. The partial pressure of the oxygen-containing source gas is not limited to a particular partial pressure; in the present disclosure, the partial pressure of the oxygen-containing source gas is preferably 0.5 to 100 times higher than the partial pressure of the metal-containing source gas and more preferably 1 to 20 times higher than the partial pressure of the metal-containing source gas. The partial pressure of the reactive gas is also not limited to a particular partial pressure; in an embodiment of the present disclosure, the partial pressure of the reactive gas is preferably 0.1 to 5 times higher than the partial pressure of the metal-containing source gas and more preferably 0.2 to 3 times higher than the partial pressure of the metal-containing source gas.

In an embodiment of the present disclosure, it is also preferable to supply dopant-containing source gas to the substrate. The dopant-containing source gas is not limited to particular dopant-containing source gas as long as the dopant-containing source gas contains dopant. The dopant is also not limited to particular dopant; in the present disclosure, the dopant preferably contains one or two or more types of elements selected from germanium, silicon, titanium, zirconium, vanadium, niobium, and tin, more preferably contains germanium, silicon, or tin, and most preferably contains germanium. By using the dopant-containing source gas as described above, it is possible to easily control the conductivity of a film to be obtained. The dopant-containing source gas preferably contains the dopant in the form of a compound (for example, a halide or oxide) and more preferably contains the dopant in the form of a halide. The partial pressure of the dopant-containing source gas is not limited to a particular partial pressure; in the present disclosure, the partial pressure of the dopant-containing source gas is preferably 1×10⁻⁷ to 0.1 times higher than the partial pressure of the metal-containing source gas and more preferably 2.5×10⁻⁶ to 7.5×10⁻² times higher than the partial pressure of the metal-containing source gas. It is to be noted that, in the present disclosure, it is preferable to supply the dopant-containing source gas to the space above the substrate along with the reactive gas.

### (Crystal Substrate)

The crystal substrate is not limited to a particular crystal substrate as long as the crystal substrate is a substrate containing a crystal substance as a major component, and may be a publicly known substrate. The crystal substrate may be an insulator substrate, a conductive substrate, or a semiconductor substrate. The crystal substrate may be a monocrystalline substrate or a polycrystalline substrate. Examples of the crystal substrate include a substrate containing a crystal substance having a corundum structure as a major component, a substrate containing a crystal substance having a β-gallia structure as a major component, a substrate having a hexagonal structure, or the like. It is to be noted that the “major component” refers to the crystal substance constituting 50% or more, preferably 70% or more, and more preferably 90% or more of the substrate in terms of composition ratio.

Examples of the substrate containing a crystal substance having a corundum structure as a major component include a sapphire substrate and an α-type gallium oxide substrate.

In an embodiment of the present disclosure, it is preferable that the crystal substrate is a sapphire substrate. Examples of the sapphire substrate include a c-plane sapphire substrate, an m-plane sapphire substrate, an α-plane sapphire substrate, an r-plane sapphire substrate, and an S-plane sapphire substrate. In the present disclosure, the sapphire substrate is preferably an m-plane sapphire substrate, an r-plane sapphire substrate, or an S-plane sapphire substrate and more preferably an r-plane sapphire substrate or an S-plane sapphire substrate. Moreover, the sapphire substrate may have an off angle. The off angle is not limited to a particular angle and is preferably 0 to 15°. It is to be noted that the thickness of the crystal substrate is not limited to a particular thickness and is preferably 50 to 2000 μm and more preferably 200 to 800 μm. Furthermore, the area of the crystal substrate is not limited to a particular area and is preferably 15 cm² or more and more preferably 100 cm² or more.

In one of embodiments of the present disclosure, it is also preferable that the crystal substrate is a β gallia substrate formed of β-Ga₂O₃. Examples of the β gallia substrate include a (100)-plane β gallia substrate and a (001)-plane β gallia substrate. Moreover, the β gallia substrate may have an off angle. The off angle is not limited to a particular angle and is preferably 0 to 15°. It is to be noted that the thickness of the crystal substrate is not limited to a particular thickness and is preferably 50 to 2000 μm and more preferably 200 to 800 μm. Furthermore, the area of the crystal substrate is not limited to a particular area and is preferably 15 cm² or more and more preferably 100 cm² or more.

Moreover, in one of embodiments of the present disclosure, since the substrate has a front surface on which an uneven portion consisting of depressions or projections is formed, it is possible to obtain the first lateral crystal growth layer of higher quality more efficiently. The uneven portion is not limited to a particular uneven portion as long as the uneven portion consists of projections or depressions; the uneven portion may be an uneven portion consisting of projections, an uneven portion consisting of depressions, or an uneven portion consisting of projections and depressions. Furthermore, the uneven portion may be formed of regular projections or depressions or formed of irregular projections or depressions. In the present disclosure, the uneven portion is preferably formed at regular intervals and more preferably patterned at regular intervals in a regular manner, and the uneven portion is most preferably a mask consisting of projections and patterned at regular intervals in a regular manner. The pattern of the uneven portion is not limited to a particular pattern and examples of the pattern include a striped pattern, a dot pattern, a meshed pattern, a random pattern or the like; in the present disclosure, the pattern of the uneven portion is preferably a dot pattern or a striped pattern and more preferably a dot pattern. It is to be noted that the dot pattern or the striped pattern may be the shape of openings of the projections. Moreover, when the uneven portion is patterned at regular intervals in a regular manner, it is preferable that the pattern shape of the uneven portion is a polygo such as a triangle, a quadrangle (for example, a square, a rectangle, or a trapezoid), a pentagon, or a hexagon or a shape such as a circle or an ellipse. It is to be noted that, when an uneven portion is formed in a dot pattern, a lattice shape such as a tetragonal lattice, an orthorhombic lattice, a triangular lattice, or a hexagonal lattice is preferably adopted as a dot lattice shape and the lattice shape of a triangular lattice is more preferably adopted as a dot lattice shape. The cross-sectional shape of the depressions or projections of the uneven portion is not limited to a particular cross-sectional shape, and examples of the cross-sectional shape of the depressions or projections of the uneven portion include the shape of a backward C, the shape of a U, the shape of an inverted U, a wave shape, a polygon such as a triangle, a quadrangle (for example, a square, a rectangle, or a trapezoid), a pentagon, or a hexagon, or the like.

A constituent material for the projections is not limited to a particular constituent material, and may be a publicly known mask material. The constituent material for the projections may be an insulator material, a conductor material, or a semiconductor material. Moreover, the constituent material may be amorphous, monocrystalline, or polycrystalline. Examples of the constituent material for the projections include oxides, nitrides, or carbides of Si, Ge, Ti, Zr, Hf, Ta, Sn or the like, carbon, diamond, metal, and a mixture of these materials. More specifically, examples of the constituent material for the projections include a Si-containing compound containing SiO₂, SiN, or polycrystalline silicon as a major component and metal (for example, noble metal such as platinum, gold, silver, palladium, rhodium, iridium, and ruthenium) having a melting point higher than the crystal growth temperature of the crystalline oxide semiconductor. It is to be noted that the content of the constituent material in the projections is preferably 50% or more, more preferably 70% or more, and most preferably 90% or more in terms of composition ratio.

A means of forming the projections may be a publicly known means and examples thereof include a publicly known patterning means such as photolithography, electron-beam lithography, laser patterning, and etching (for example, dry etching or wet etching) that is performed afterward. In the present disclosure, the projections preferably have a striped pattern or a dot pattern and more preferably have a dot pattern. It is to be noted that the dot pattern or the striped pattern may be the shape of openings of the projections. Moreover, in the present disclosure, it is also preferable that the crystal substrate is a patterned sapphire substrate (PSS). The pattern shape of the PSS is not limited to a particular pattern shape and may be a publicly known pattern shape. Examples of the pattern shape include a cone, a bell, a dome, a hemisphere, and a square or triangular pyramid; in the present disclosure, it is preferable that the pattern shape is a cone. Furthermore, the pitch of the pattern shape is also not limited to a particular pitch; in an embodiment of the present disclosure, the pitch of the pattern shape is preferably 100 μm or less and more preferably 1 to 50 μm.

The depressions are not limited to particular depressions, and may be what is similar to the constituent material for the projections mentioned above or a substrate. In the present disclosure, it is preferable that the depressions are a gap layer provided on a front surface of a substrate. A means similar to the means of forming the projections can be used as a means of forming the depressions. The gap layer can be formed on a front surface of a substrate by providing a groove in the substrate by a publicly known groove forming means. The groove width, the groove depth, the terrace width and so forth of the gap layer are not limited to particular groove width, groove depth, terrace width and so forth unless they interfere with the object of the present disclosure, and can be appropriately set. Moreover, the gap layer may contain air or may contain inert gas or the like.

Hereinafter, one example of an embodiment of a substrate that is suitably used in the present disclosure will be described using the drawings.

FIG. 12 shows one form of an uneven portion provided on a crystal growth surface of a crystal substrate in the present disclosure. The uneven portion of FIG. 12 is configured with a crystal substrate 1 and projections 2a on a crystal growth surface 1a. The projections 2a have a striped pattern, and the projections 2a having a striped pattern are arranged at regular intervals on the crystal growth surface 1a of the crystal substrate 1. It is to be noted that the projections 2a are formed of a silicon-containing compound such as SiO₂ and can be formed using a publicly known means such as photolithography.

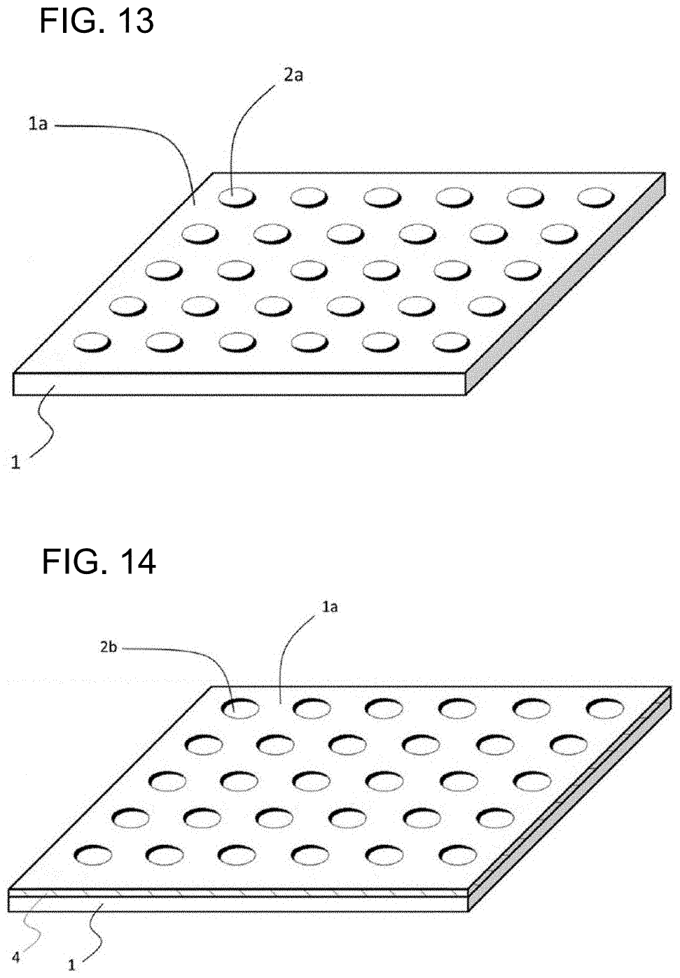

FIG. 13 shows one form of an uneven portion provided on a crystal growth surface of a crystal substrate in the present disclosure and shows a form different from the form of FIG. 12. As in the case of FIG. 12, the uneven portion of FIG. 13 is configured with a crystal substrate 1 and projections 2a provided on a crystal growth surface 1a. The projections 2a have a dot pattern, and the projections 2a having a dot pattern are arranged at regular intervals in a regular manner on the crystal growth surface 1a of the crystal substrate 1. It is to be noted that the projections 2a are formed of a silicon-containing compound such as SiO₂ and can be formed using a publicly known means such as photolithography.

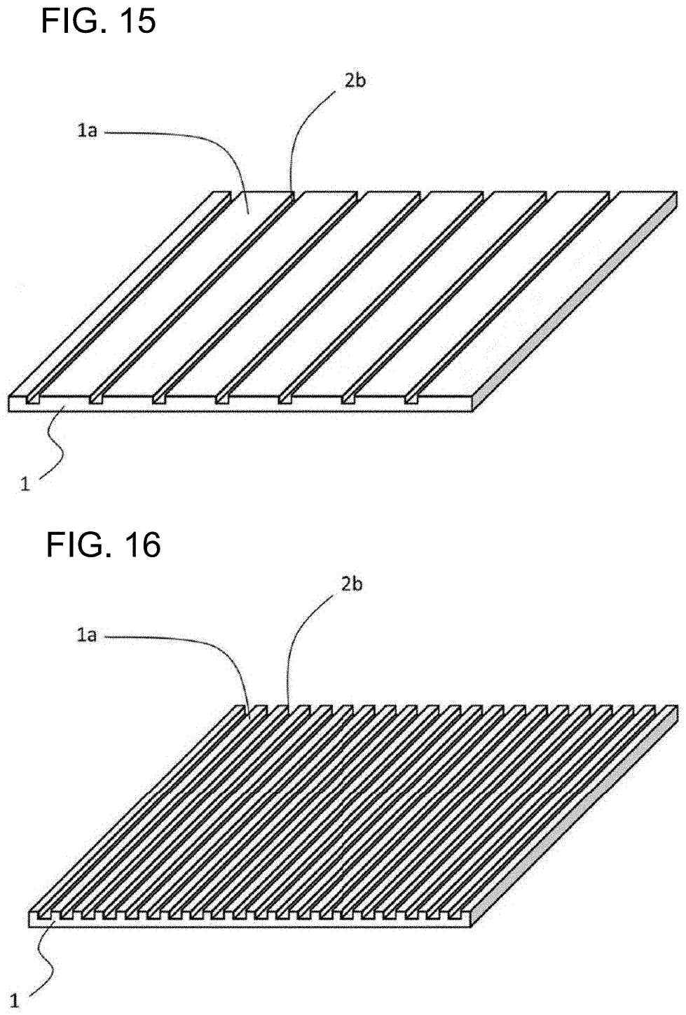

FIG. 14 shows one form of an uneven portion provided on a crystal growth surface of a crystal substrate in the present disclosure. FIG. 14 includes depressions 2b, not projections. The uneven portion of FIG. 14 are configured with a crystal substrate 1 and a mask layer 4. The mask layer 4 is formed on a crystal growth surface 1a and has holes having a dot pattern. The crystal substrate 1 is exposed from the holes of the dots of the mask layer 4, and the depressions 2b having a dot pattern are formed on the crystal growth surface 1a. It is to be noted that the depressions 2b can be obtained by forming the mask layer 4 using a publicly known means such as photolithography. Moreover, the mask layer 4 is not limited to a particular mask layer as long as the mask layer 4 is a layer that can inhibit longitudinal crystal growth. Examples of a constituent material for the mask layer 4 include publicly known materials such as a silicon-containing compound such as SiO₂.

FIG. 15 shows one form of an uneven portion provided on a crystal growth surface of a crystal substrate in the present disclosure. The uneven portion of FIG. 15 is configured with a crystal substrate 1 and a gap layer. The gap layer has a striped pattern, and depressions 2b having a striped pattern are arranged at regular intervals on a crystal growth surface 1a of the crystal substrate 1. It is to be noted that the depressions 2b can be formed by a publicly known groove forming means.

Moreover, one form of an uneven portion provided on a crystal growth surface 1a of a crystal substrate 1 in the present disclosure is also shown in FIG. 16. The uneven portion of FIG. 16 has depressions 2b which are different from the depressions 2b of FIG. 15 in spacing between the depressions 2b, and a spacing therebetween is smaller in width. That is, the depressions 2b have a large terrace width in FIG. 15 and a small terrace width in FIG. 16. As in the case of the depressions of FIG. 15, the depressions 2b of FIG. 16 can also be formed using a publicly known groove forming means.

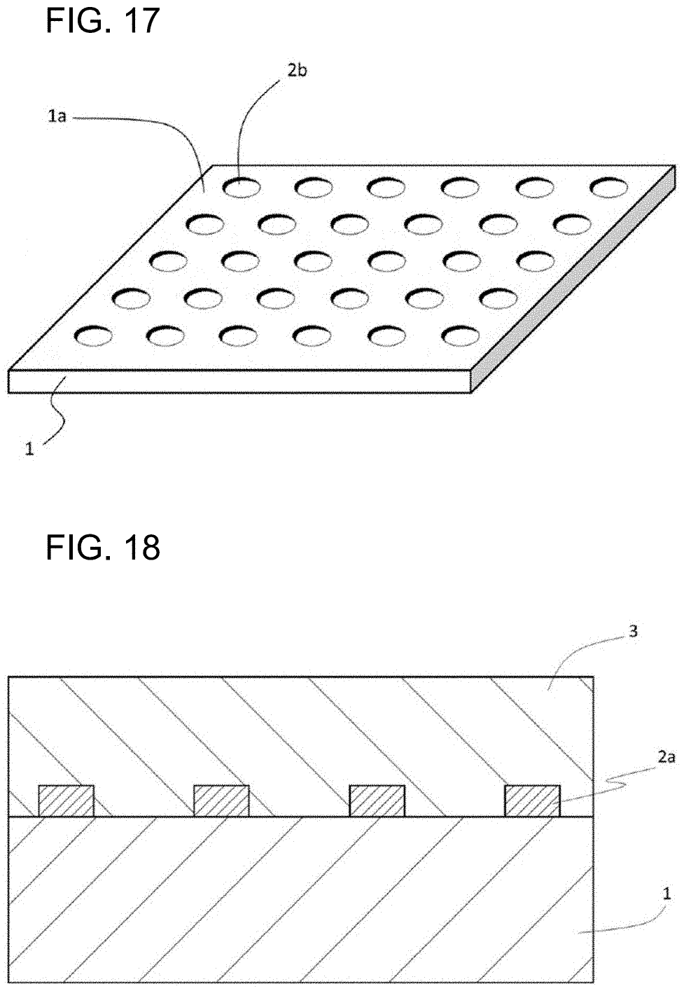

As in the case of FIGS. 15 and 16, FIG. 17 shows one form of an uneven portion provided on a crystal growth surface of a crystal substrate in the present disclosure, and the uneven portion of FIG. 17 is configured with a crystal substrate 1 and a gap layer. Unlike FIGS. 15 and 16, the gap layer has a dot pattern, and depressions 2b having a dot pattern are arranged at regular intervals in a regular manner on a crystal growth surface 1a of the crystal substrate 1. It is to be noted that the depressions 2b can be formed by a publicly known groove forming means.

The width and height of projections of an uneven portion and the width and depth of depressions, the spacing between the depressions and so forth of an uneven portion are not limited to particular width, height, depth, spacing and so forth. In the present disclosure, each of them falls within the range of about 10 nm to about 1 mm, for example; with each of them being preferably about 10 nm to about 300 μm, more preferably about 10 nm to about 1 μm, and most preferably about 100 nm to about 1 μm.

FIG. 18 is a sectional view of the relationship between an uneven portion and a crystal growth layer which are formed on a front surface of a substrate that is suitably used in the present disclosure. In a crystalline multilayer structure of FIG. 18, projections 2a are formed on a crystal substrate 1 and an epitaxial layer 3 is formed thereon by crystal growth. In the epitaxial layer 3, lateral crystal growth of a crystalline semiconductor having a corundum structure (a β gallia structure) is also performed by the projections 2a, and a crystal film having a corundum structure (a gallia structure) and obtained in this manner is a high-quality crystal film that is completely different from a crystal film having a corundum structure (a β gallia structure) and has no uneven portion. Moreover, an example in which a buffer layer is provided is shown in FIG. 19. In a crystalline multilayer structure of FIG. 19, a buffer layer 3a is formed on a crystal substrate 1 and projections 2a are formed on the buffer layer 3a. An epitaxial layer 3 is formed on the projections 2a. As in the case of FIG. 18, in the crystalline multilayer structure of FIG. 19, lateral crystal growth of a crystal film having a corundum structure (a β gallia structure) is performed by the projections 2a, and a high-quality crystal film having a corundum structure (a β gallia structure) is formed.

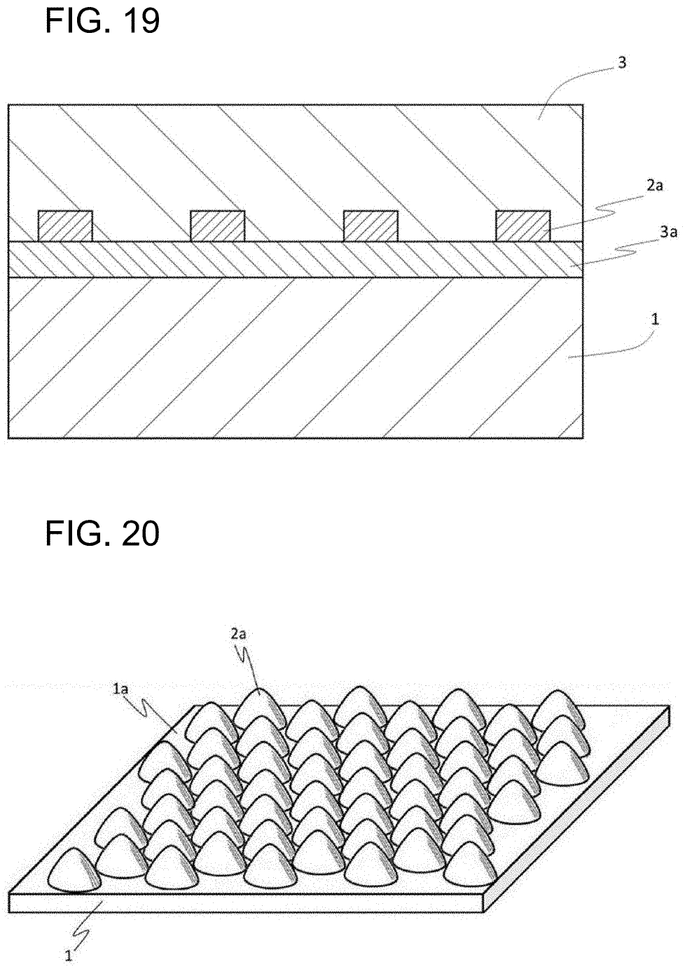

FIG. 20 shows one form of an uneven portion having a dot pattern and provided on a front surface of a substrate in an embodiment of the present disclosure. The uneven portion of FIG. 20 is configured with a substrate 1 and a plurality of projections 2a provided on a front surface 1a of the substrate 1. FIG. 21 shows a front surface of the uneven portion shown in FIG. 20 and viewed from an overhead position. As is clear from FIGS. 20 and 21, the uneven portion has a configuration in which the conical projections 2a are formed on a triangular lattice on the front surface 1a of the substrate 1. The projections 2a can be formed by a publicly known processing means such as photolithography. It is to be noted that lattice points of the triangular lattice are provided at spacings of a fixed interval a. The interval a is not limited to a particular interval; in the present disclosure, the interval a is preferably 100 μm or less and more preferably 1 to 50 μm. The interval a here refers to the distance between the height peak positions (that is, lattice points) of adjacent projections 2a.

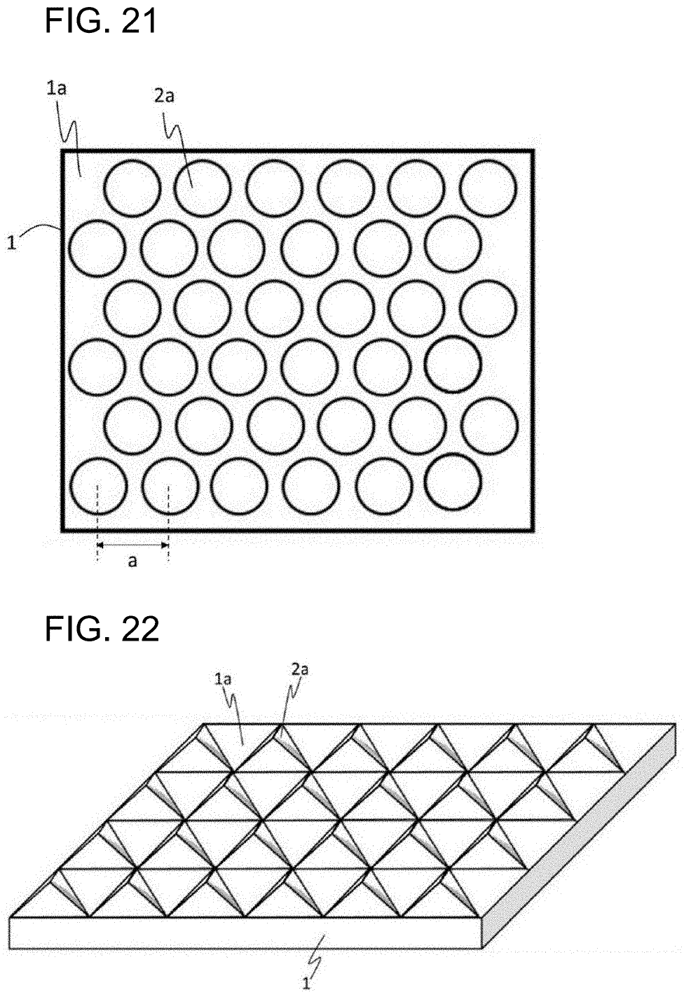

FIG. 22 shows one form of an uneven portion having a dot pattern and provided on a front surface of a substrate in an embodiment of the present disclosure and shows a form different from the form of FIG. 20. The uneven portion of FIG. 22 is configured with a substrate 1 and projections 2a provided on a front surface 1a of the substrate 1. FIG. 23 shows an overhead view of a front surface of the uneven portion shown in FIG. 22. As is clear from FIGS. 22 and 23, the uneven portion has a configuration in which the triangular pyramid projections 2a are formed on a triangular lattice on the front surface 1a of the substrate 1. The projections 2a can be formed by a publicly known processing means such as photolithography. It is to be noted that lattice points of the triangular lattice are provided at spacings of a fixed interval a. The interval a is not limited to a particular interval; in the present disclosure, the interval a is preferably 0.5 to 10 μm, more preferably 1 to 5 μm, and most preferably 1 to 3 μm.

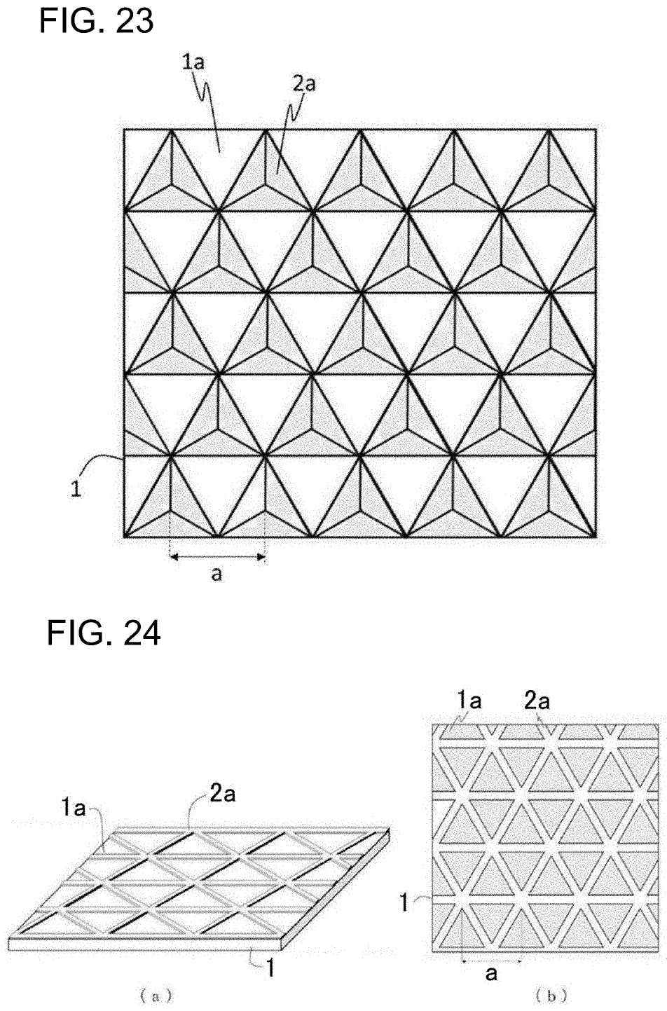

FIG. 24(a) shows one form of an uneven portion provided on a front surface of a substrate in an embodiment of the present disclosure and FIG. 24(b) schematically shows a front surface of the uneven portion shown in FIG. 24(a). The uneven portion of FIG. 24 is configured with a substrate 1 and projections 2a having a triangular pattern and provided on a front surface 1a of the substrate 1. It is to be noted that the projections 2a are formed of a material for the substrate or a silicon-containing compound such as SiO₂ and can be formed using a publicly known means such as photolithography. It is to be noted that an interval a between intersection points of the triangular pattern is not limited to a particular interval; in an embodiment of the present disclosure, the interval a is preferably 0.5 to 10 μm and more preferably 1 to 5 μm.

As in the case of FIG. 24(a), FIG. 25(a) shows one form of an uneven portion provided on a front surface of a substrate in an embodiment of the present disclosure and FIG. 25(b) schematically shows a front surface of the uneven portion shown in FIG. 25(a). The uneven portion of FIG. 25(a) is configured with a substrate 1 and a gap layer having a triangular pattern. It is to be noted that depressions 2b can be formed by a publicly known groove forming means such as laser dicing. It is to be noted that an interval a between intersection points of the triangular pattern is not limited to a particular interval; in the present disclosure, the interval a is preferably 0.5 to 10 μm and more preferably 1 to 5 μm.

The width and height of projections of an uneven portion and the width and depth of depressions, the spacing between the depressions and so forth of an uneven portion are not limited to particular width, height, depth, spacing and so forth. In an embodiment of the present disclosure, each of them falls within the range of about 10 nm to about 1 mm, for example; each of them is preferably about 10 nm to about 300 μm, more preferably about 10 nm to about 1 μm, and most preferably about 100 nm to about 1 μm. It is to be noted that the uneven portion may be formed directly on the substrate or provided with another layer placed between the uneven portion and the substrate.

In an embodiment of the present disclosure, a buffer layer including a stress relaxation layer and so forth may be provided on the substrate. It is to be noted that the buffer layer preferably has a thermal conductivity of 100 W/m·K or higher at ambient temperature. Moreover, in an embodiment of the present disclosure, it is preferable that the substrate has the buffer layer in a part of a front surface or all over the front surface. A means of forming the buffer layer is not limited to a particular means and may be a publicly known means. Examples of the forming means include a spray method, mist CVD, HVPE, MBE, MOCVD, and a sputtering process. Hereinafter, a suitable embodiment in which the buffer layer is formed by mist CVD will be described in more detail.

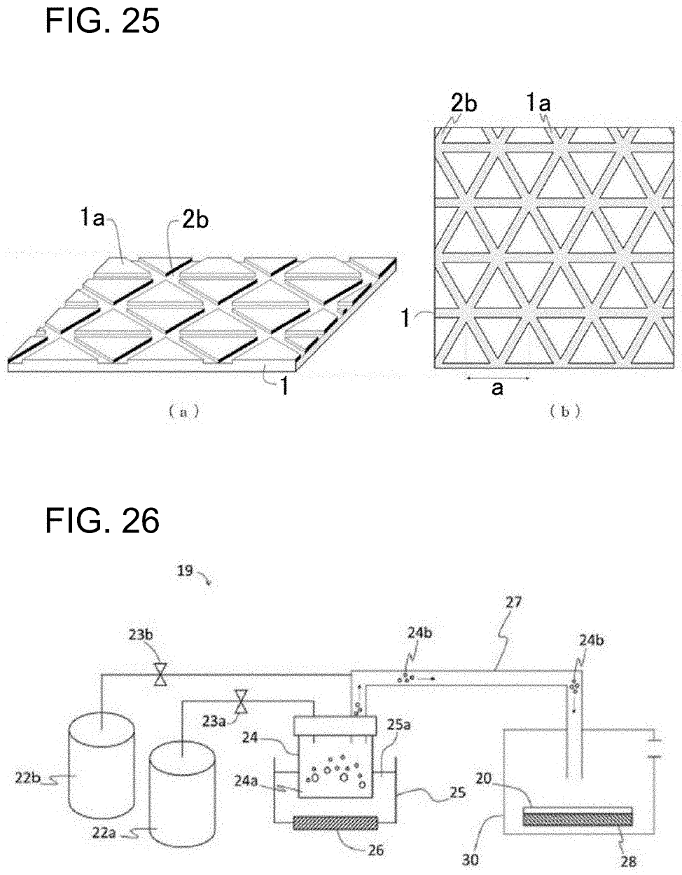

The buffer layer can be suitably formed using mist CVD equipment shown in FIG. 26, for example, by atomizing a raw material solution or turning the raw material solution into droplets (an atomization process), conveying the obtained atomized droplets to the substrate using carrier gas (a conveying process), and then making the atomized droplets thermally react with each other in a part of a front surface or all over the front surface of the substrate (a buffer layer formation process). It is to be noted that, in the present disclosure, the crystal growth layer can also be formed in a similar manner.

### (Atomization Process)

The atomization process atomizes the raw material solution and obtains the atomized droplets. The means of atomizing the raw material solution is not limited to a particular means as long as the means can atomize the raw material solution, and may be a publicly known means; in the embodiment of the present disclosure, an atomizing means using ultrasonic waves is preferable. The atomized droplets obtained using ultrasonic waves are preferable because the initial velocity thereof is zero, which allows them to be suspended in the air, and are very suitable because they are mist that is suspended in the space and can be conveyed as gas, not being sprayed like a spray, for example, and therefore cause no damage by collision energy. The droplet size of the atomized droplets is not limited to a particular size and may be a droplet of about a few mm; the droplet size is preferably 50 μm or less and more preferably 0.1 to 10 μm.

### (Raw Material Solution)

The raw material solution is not limited to a particular raw material solution as long as the raw material solution is a solution that can be atomized and allows the buffer layer to be obtained by mist CVD. Examples of the raw material solution include an aqueous solution of an organometallic complex (for example, an acetylacetonato complex) or a halide (for example, fluoride, chloride, bromide, or iodide) of metal for atomization. The metal for atomization is not limited to particular metal, and examples of such metal for atomization include one or two or more types of metal selected from aluminum, gallium, indium, iron, chromium, vanadium, titanium, rhodium, nickel, cobalt, iridium and so forth. In the present disclosure, the metal for atomization preferably contains at least gallium, indium, or aluminum and more preferably contains at least gallium. The content of the metal for atomization in the raw material solution is not limited to a particular content unless it interferes with the object of the present disclosure; the content of the metal for atomization in the raw material solution is preferably 0.001 to 50 mol % and more preferably 0.01 to 50 mol %.

Moreover, it is also preferable that the raw material solution contains dopant. By making the raw material solution contain dopant, it is possible to easily control the electrical conductivity of the buffer layer without a breakdown of a crystal structure without performing ion implantation or the like. In the present disclosure, the dopant is preferably tin, germanium, or silicon, more preferably tin or germanium, and most preferably tin. In general, the concentration of the dopant may be about 1×10¹⁶/cm³ to 1×10²²/cm³; the concentration of the dopant may be set at a low concentration of about 1×10¹⁷/cm³ or less or the raw material solution may be made to contain the dopant at a high concentration of about 1×10²⁰/cm³ or more. In the present disclosure, the concentration of the dopant is preferably 1×10²⁰/cm³ or less and more preferably 5×10¹⁹/cm³ or less.

A solvent of the raw material solution is not limited to a particular solvent and may be an inorganic solvent such as water, an organic solvent such as alcohol, or a mixed solvent of an inorganic solvent and an organic solvent. In the present disclosure, the solvent preferably contains water, is more preferably water or a mixed solvent of water and alcohol, and is most preferably water. More specifically, examples of the water include pure water, ultrapure water, tap water, well water, mineral water, mineralized water, hot spring water, spring water, fresh water, and seawater; in the present disclosure, ultrapure water is preferable.

### (Conveying Process)

In the conveying process, the atomized droplets are conveyed into a film formation chamber by carrier gas. The carrier gas is not limited to particular carrier gas unless it interferes with the object of the present disclosure, and suitable examples of the carrier gas include oxygen, ozone, inert gas such as nitrogen and argon, reducing gas such as hydrogen gas and forming gas, or the like. Moreover, one type of carrier gas may be used; two or more types of carrier gas may be used and dilution gas (for example, 10-fold dilution gas) with a decreased flow rate, for example, may be additionally used as second carrier gas. Furthermore, instead of one carrier gas supply point, two or more carrier gas supply points may be provided. The flow rate of carrier gas is not limited to a particular flow rate and is preferably 0.01 to 20 L/min and more preferably 1 to 10 L/min. When dilution gas is used, the flow rate of the dilution gas is preferably 0.001 to 2 L/min and more preferably 0.1 to 1 L/min.

### (Buffer Layer Formation Process)

In the buffer layer formation process, the buffer layer is formed on a substrate by making the atomized droplets thermally react with each other inside the film formation chamber. A thermal reaction only has to make the atomized droplets react with each other by heat, and the reaction conditions and so forth are also not limited to particular reaction conditions and so forth unless they interfere with the object of the present disclosure. In this process, the thermal reaction is generally carried out at a temperature equal to or higher than the evaporation temperature of a solvent; the temperature is preferably lower than excessively high temperatures (for example, 1000° C.), more preferably 650° C. or lower, and most preferably 400 to 650° C. Moreover, the thermal reaction may be carried out under any one of the following atmospheres: under vacuum, under a non-oxygen atmosphere, under a reducing gas atmosphere, and under an oxygen atmosphere and may be carried out under any one of the following conditions: under atmospheric pressure, under increased pressure, and under reduced pressure unless it interferes with the object of the present disclosure; in the present disclosure, it is preferable that the thermal reaction is carried out under atmospheric pressure. It is to be noted that the thickness of the buffer layer can be set by adjusting the formation time.

After a buffer layer is formed in a part of a front surface or all over the front surface on the substrate in the above-mentioned manner, the first lateral crystal growth layer is formed on the buffer layer by the above-mentioned preferred method of forming the first lateral crystal growth layer or method of forming the buffer layer, which makes it possible to further reduce the number of defects such as tilt in the first lateral crystal growth layer and thereby further improve film quality.

Moreover, the buffer layer is not limited to a particular buffer layer; in the present disclosure, it is preferable that the buffer layer contains a metal oxide as a major component. Examples of the metal oxide include a metal oxide containing one or two or more types of metal selected from aluminum, gallium, indium, iron, chromium, vanadium, titanium, rhodium, nickel, cobalt, iridium and so forth. In the disclosure, the metal oxide preferably contains one or two or more types of elements selected from indium, aluminum, and gallium, more preferably contains at least indium or/and gallium, and most preferably contains at least gallium. As one of embodiments of a film formation method of the present disclosure, the buffer layer may contain a metal oxide as a major component and the metal oxide contained in the buffer layer may contain gallium and have a lower content of aluminum than that of gallium. By using the buffer layer having a lower content of aluminum than that of gallium, it is possible not only to achieve favorable crystal growth, but also to achieve favorable high-temperature growth. Furthermore, as one of embodiments of the film formation method of the present disclosure, the buffer layer may contain a superlattice structure. Using the buffer layer containing a superlattice structure not only achieves favorable crystal growth, but also makes it easier to prevent warpage and the like at the time of crystal growth. It is to be noted that a “major component” here means that the metal oxide constitutes preferably 50% or more, more preferably 70% or more, and further preferably 90% or more of all the components of the buffer layer in terms of atom ratio and means that the metal oxide may constitute 100% of all the components of the buffer layer in terms of atom ratio. The crystal structure of the crystalline oxide semiconductor is not limited to a particular crystal structure; in the present disclosure, the crystal structure of the crystalline oxide semiconductor is preferably a corundum structure. Moreover, a major component of the first lateral crystal growth layer and a major component of the buffer layer may be the same or different from each other unless it interferes with the object of the present disclosure; in the present disclosure, it is preferable that a major component of the first lateral crystal growth layer and a major component of the buffer layer are the same.

In the embodiment of the present disclosure, metal-containing source gas, oxygen-containing source gas, reactive gas, and dopant-containing source gas if necessary are supplied to the space above the substrate on which the buffer layer may be provided, and film formation is performed with the reactive gas being circulated. In the present disclosure, it is preferable that the film formation is performed on the heated substrate. The film formation temperature is not limited to a particular temperature unless it interferes with the object of the present disclosure, and the film formation temperature is preferably 900° C. or lower, more preferably 700° C. or lower, and most preferably 400 to 700° C. Moreover, the film formation may be performed under any one of the following atmospheres: under vacuum, under non-vacuum, under a reducing gas atmosphere, under an inert gas atmosphere, and under an oxidation gas atmosphere and may be performed under any one of the following conditions: under ordinary pressure, under atmospheric pressure, under increased pressure, and under reduced pressure unless it interferes with the object of the present disclosure; in the embodiment of the present disclosure, it is preferable that the film formation is performed under ordinary pressure or under atmospheric pressure. It is to be noted that a film thickness can be set by adjusting the film formation time.

The first lateral crystal growth layer generally contains a crystalline metal oxide as a major component. Examples of the crystalline metal oxide include a metal oxide containing one or two or more types of metal selected from aluminum, gallium, indium, iron, chromium, vanadium, titanium, rhodium, nickel, cobalt, iridium and so forth. In the present disclosure, the crystalline metal oxide preferably contains one or two or more types of elements selected from indium, aluminum, and gallium, more preferably contains at least indium or/and gallium, and is most preferably crystalline gallium oxide or a mixed crystal thereof. It is to be noted that, in a first lateral crystal growth layer in an embodiment of the present disclosure, a “major component” means that the crystalline metal oxide constitutes preferably 50% or more, more preferably 70% or more, and further preferably 90% or more of all the components of the first lateral crystal growth layer in terms of atom ratio and means that the crystalline metal oxide may constitute 100% of all the components of the first lateral crystal growth layer in terms of atom ratio. In an embodiment of the present disclosure, it is possible to obtain a crystal growth film having a corundum structure (a β gallia structure) by performing the film formation using a substrate containing a corundum structure (a gallia structure) as the substrate. The crystalline metal oxide may be monocrystalline or polycrystalline; in an embodiment of the present disclosure, it is preferable that the crystalline metal oxide is monocrystalline. Moreover, the upper limit of the thickness of the first lateral crystal growth layer is not limited to a particular upper limit and is 100 μm, for example; the lower limit of the thickness of the first lateral crystal growth layer is also not limited to a particular lower limit and is preferably 3 μm, more preferably 10 μm, and most preferably 20 μm. In the present disclosure, the thickness of the first lateral crystal growth layer is preferably 3 to 100 μm, more preferably 10 to 100 μm, and most preferably 20 to 100 μm.

In the present disclosure, it is preferable that the projections are formed on the first lateral crystal growth layer as a mask. By forming the mask on the first lateral crystal growth layer as described above, it is possible not only to achieve a mere improvement in crystallinity, but also to lower a dislocation density more satisfactorily and achieve a large-area crystal film. It is to be noted that the mask may be similar to the projections. In the present disclosure, it is preferable that the first lateral crystal growth layer includes two or more lateral crystal portions and the mask is placed on each of the two or more lateral crystal portions. It is to be noted that the two or more lateral crystal portions may be two or more lateral crystal portions obtained before the association of two or more first lateral crystal growth portions during the formation thereof in the first lateral crystal growth. By providing the mask on the lateral crystal portion as described above, it is possible to prevent warpage, cracks and so forth caused by thermal stress that is produced by the association in a first lateral crystal growth. It is preferable that the mask on the lateral crystal growth layer is patterned at regular intervals in a regular manner, and it is preferable that the spacing of the mask on the lateral crystal growth layer is smaller than the spacing of the mask on the substrate. By setting the spacing as described above, it is possible to achieve further relaxation of thermal stress or the like and more easily obtain a large-area crystal film having high crystallinity. It is to be noted that the spacing of the mask on the first lateral crystal growth layer is not limited to a particular spacing and is preferably 1 to 50 μm.

### (Support)

The support is not limited to a particular support as long as the support can support the crystal film and has a thermal conductivity of 100 W/m·K or higher at ambient temperature, and may be a publicly known support. The shape or the like of the support is also not limited to a particular shape or the like and the support may have various shapes; in the present disclosure, it is preferable that the support is a substrate. It is to be noted that the substrate may have one or two or more films, other layers or the like on a front surface. In the present disclosure, the support preferably contains silicon and is more preferably a SiC substrate or a Si substrate. By using such a preferred support, it is possible to obtain a multilayer structure having better semiconductor characteristics. Moreover, the area of the support is also not limited to a particular area; the area of the support is preferably 15 cm² or more because this makes it possible to use the support in semiconductor devices and so forth in a more industrially advantageous manner, and the area of the support is more preferably 100 cm² or more. Furthermore, in the present disclosure, the support is preferably a 4-inch substrate, a 6-inch substrate, an 8-inch substrate, or a 12-inch substrate because this makes it possible to use the support in semiconductor devices and so forth in a more industrially advantageous manner.

A method of adhering the support to the crystal growth layer is not limited to a particular method; a publicly known means may be used and the support may be mechanically, physically, or chemically adhered to the crystal growth layer. Moreover, a method of separating the crystal growth substrate is also not limited to a particular method; a publicly known means may be used and a mechanical separating means, a physical separating means, or a chemical separating means may be used.

Hereinafter, a suitable method of producing a multilayer structure of the present disclosure will be described in more detail using the drawings.

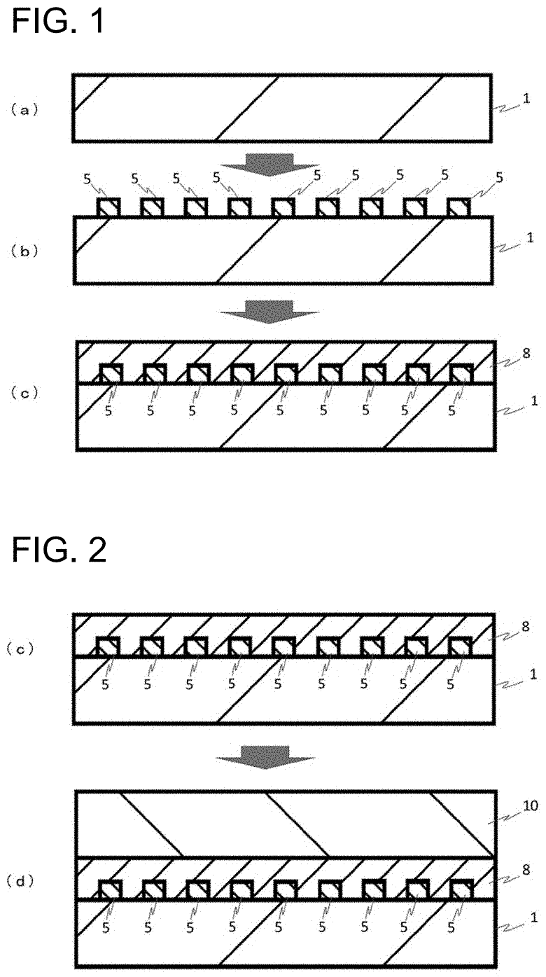

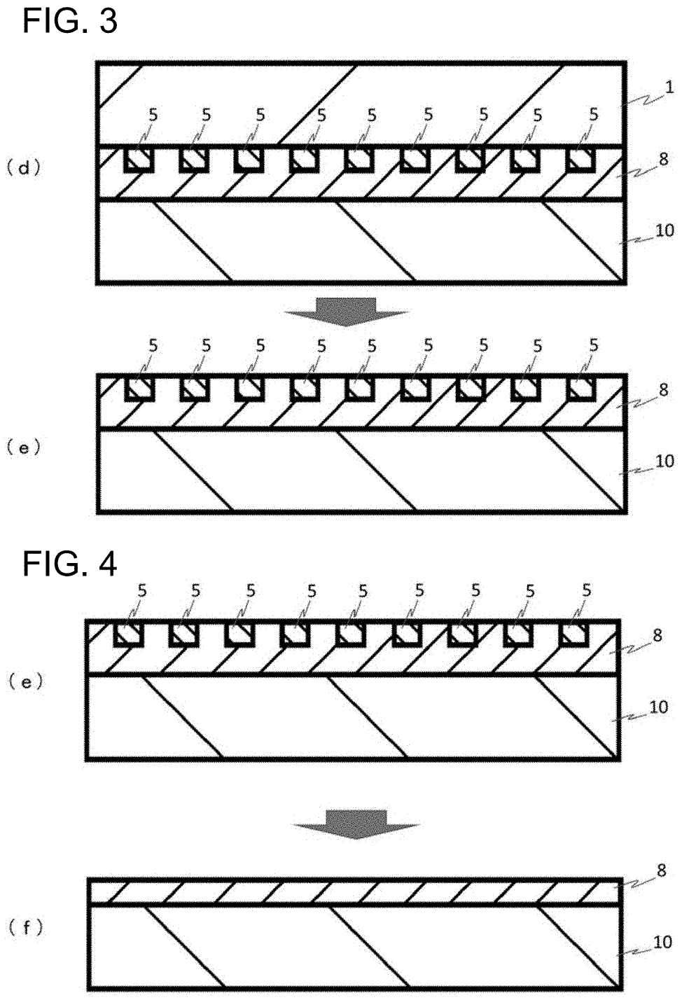

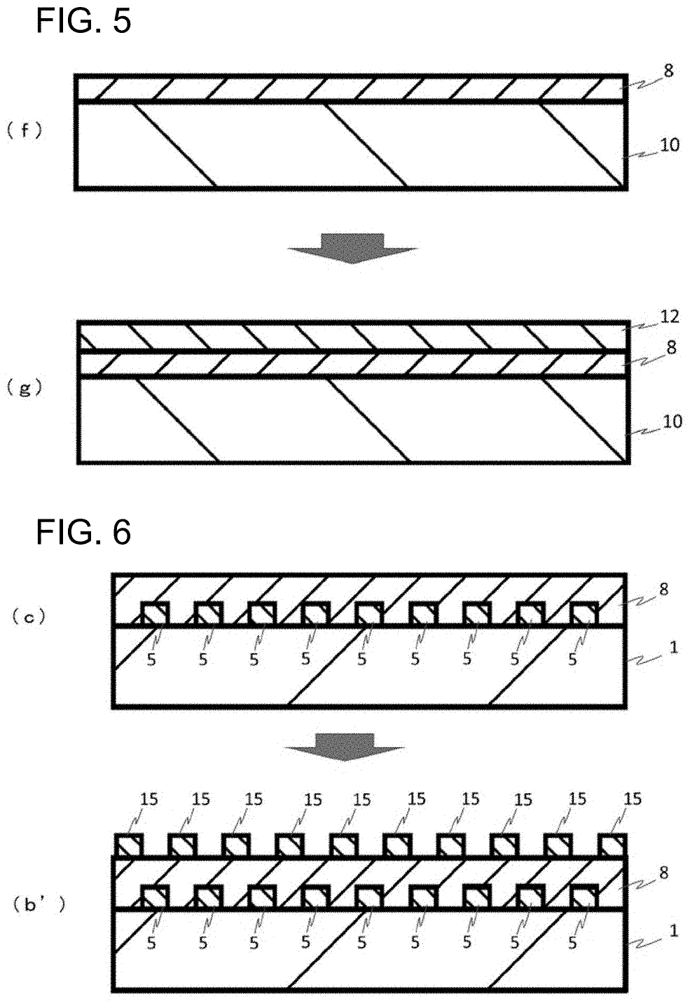

An ELO mask is formed on a front surface as a crystal growth substrate. It is to be noted that a sapphire substrate is used as the crystal growth substrate. In the present disclosure, it is preferable to use a sapphire substrate whose principal plane is an r plane or an S plane as the sapphire substrate. FIG. 1(a) shows a sapphire substrate 1. As shown in FIG. 1(b), an ELO mask 5 is formed on a crystal growth surface of the sapphire substrate 1. The ELO mask 5 is not limited to a particular ELO mask; it is preferable that the ELO mask 5 has a striped pattern or a dot pattern. A crystal growth layer is formed using the crystal growth substrate of FIG. 1(b), and a multilayer structure of FIG. 1(c) is obtained. The multilayer structure (c) has a crystal growth layer (a first lateral crystal growth layer) 8 formed on the sapphire substrate 1 with the ELO mask 5 on a front surface. After the multilayer structure (c) is obtained, a support substrate 10 is adhered to the crystal growth layer 8, and a multilayer structure of FIG. 2(d) is obtained. After the multilayer structure (d) is obtained, the sapphire substrate 1 is separated by conventional means such as a mechanical separating means, for example, and a multilayer structure of FIG. 3(e) is obtained. After the multilayer structure (e) is obtained, the ELO mask 5 is removed by conventional means such as CMP, for example, and a multilayer structure of FIG. 4(f) is obtained. After the multilayer structure (f) is obtained, crystal growth is performed again on the crystal growth layer 8 by conventional means such as HVPE or mist CVD, for example, whereby a regrowth layer 12 is formed and a multilayer structure of FIG. 5(g) is obtained. The multilayer structure (f) or (g) obtained in this way has a large-area crystal film having a favorable film thickness distribution and a film thickness of 30 μm or less and achieves good heat dissipation.

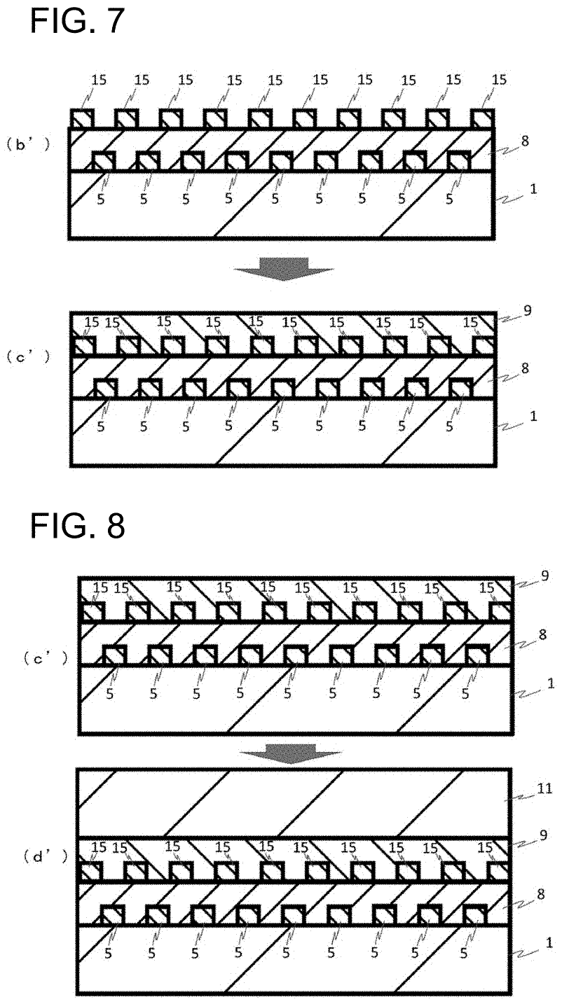

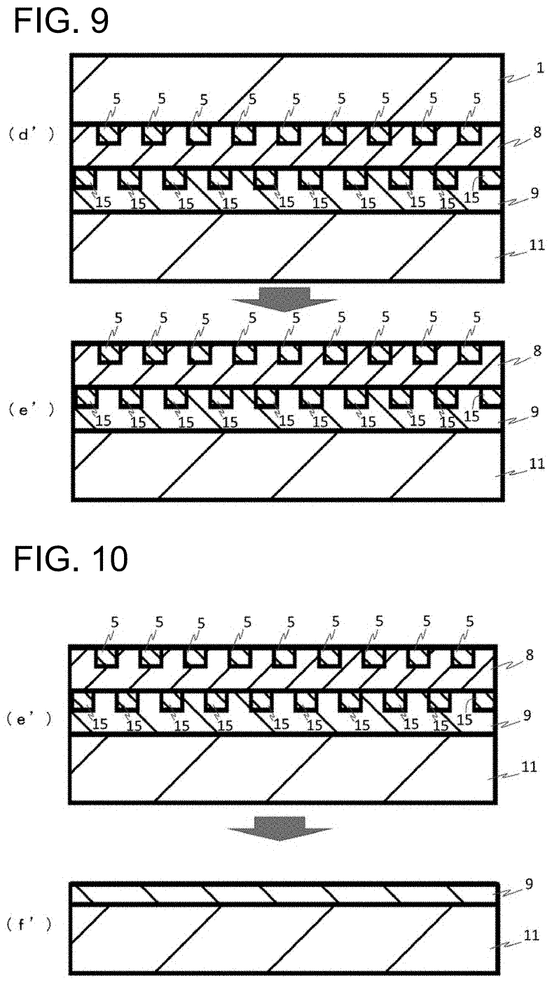

FIGS. 6 to 10 show a case where the multilayer structure is fabricated by forming the projections on the first lateral crystal growth layer as a mask as one suitable example of a process of producing a multilayer structure of the present disclosure. FIG. 6(c) shows a multilayer structure having a crystal growth layer 8 formed on a sapphire substrate 1 with an ELO mask 5 on a front surface. After the multilayer structure (c) is obtained, a second mask 15 is formed on the first lateral crystal growth layer 8, and a multilayer structure of FIG. 6(b′) is obtained. A second lateral crystal growth layer is formed on the multilayer structure (b′), and a multilayer structure of FIG. 7(c′) is obtained. After the multilayer structure (c′) is obtained, a support substrate 11 is adhered to the second lateral crystal growth layer, and a multilayer structure of FIG. 8(d′) is obtained. After the multilayer structure (d′) is obtained, the sapphire substrate 1 is separated by conventional means such as a mechanical separating means, for example, and a multilayer structure of FIG. 9(e′) is obtained. After the multilayer structure (e′) is obtained, the ELO mask 5, the first lateral crystal growth layer 8, and the second mask 15 are removed by conventional means such as CMP, for example, and a multilayer structure of FIG. 10(f) is obtained. The multilayer structure (f) obtained in this way has a large-area crystal film having a favorable film thickness distribution, a film thickness of 30 μm or less, and a lower dislocation density and achieves good heat dissipation.

Moreover, in the present disclosure, it is preferable to obtain a third lateral crystal growth layer by providing a mask on the second lateral crystal growth layer and performing another lateral crystal growth. Doing so makes it easier to obtain a large-area crystal film that is 2 inches or larger and has a lower dislocation density (for example, 1.0×10⁵/cm² or less).

It is to be noted that, in the present disclosure, the first lateral crystal growth layer or the second lateral crystal growth layer may be formed as a separation sacrifice layer.

The multilayer structure of the present disclosure can be suitably used in a semiconductor device including at least an electrode and a semiconductor layer in particular and is particularly useful for power devices. In the present disclosure, it is preferable that a crystal film of the multilayer structure is a semiconductor film and the semiconductor film is used as the semiconductor layer. Examples of semiconductor devices that are formed using the multilayer structure include transistors such as a MIS and a HEMT and TFTs, a Schottky barrier diode using the semiconductor-metal junction, a PN or PIN diode combined with another P layer, and a light-receiving or emitting element. In the present disclosure, the crystal film may be used in a semiconductor device or the like as it is, or the crystal film may be applied to a semiconductor device or the like after using a publicly known means such as separating the crystal film from the substrate or the like.

The semiconductor device of the present disclosure is suitably used as a semiconductor device by being bonded to a leadframe, a circuit board, a heat dissipation substrate or the like by a bonding member based on conventional means in addition to the above-described matter, is suitably used as a power module, an inverter, or a converter in particular, and is suitably used in a semiconductor system or the like using a power supply device, for example. One suitable example of the semiconductor device bonded to a leadframe, a circuit board, or a heat dissipation substrate is shown in FIG. 30. The semiconductor device of FIG. 30 includes a semiconductor element 500 bonded on both sides to leadframes, circuit boards, or heat dissipation substrates 502 by solder 501. This configuration can achieve a semiconductor device with good heat dissipation. It is to be noted that, in the present disclosure, it is preferable that a bonding member such as solder is encapsulated in resin.

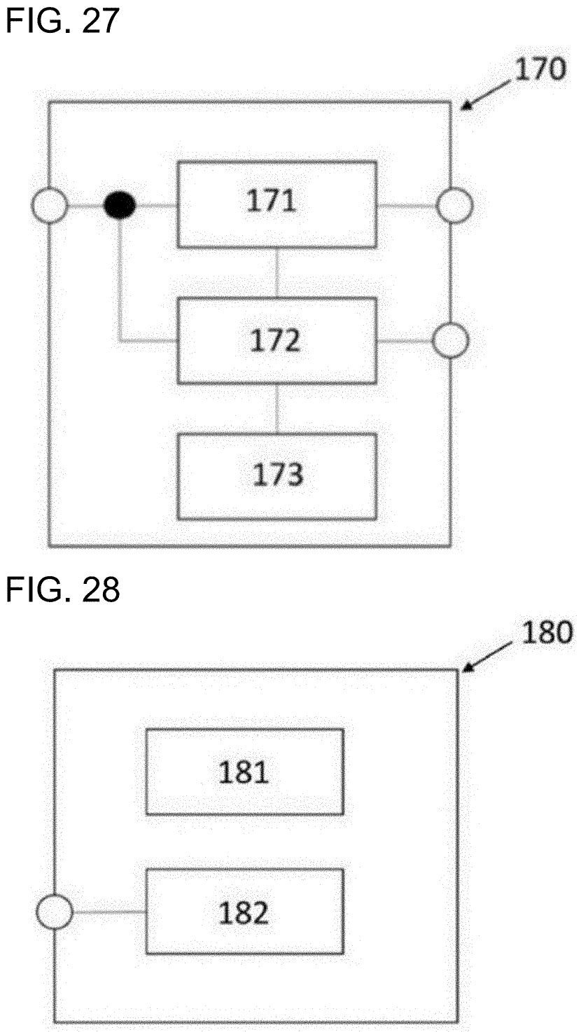

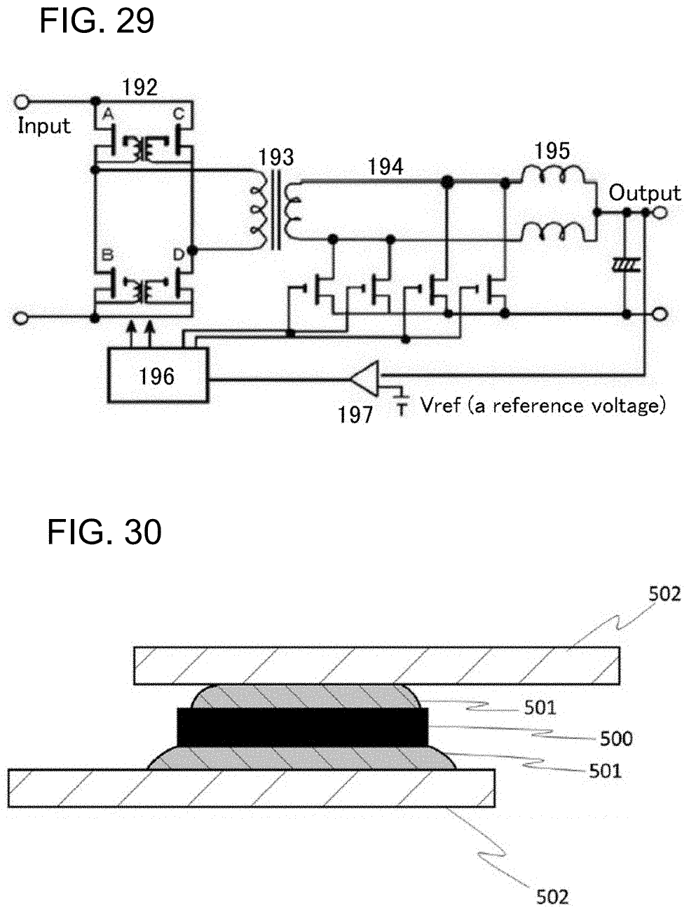

Moreover, the power supply device can be fabricated from the semiconductor device or as a power supply device including the semiconductor device by, for example, connecting it to a wiring pattern or the like using a publicly known method. FIG. 27 shows a power supply system 170 configured with a plurality of the power supply devices 171 and 172 and a control circuit 173. As shown in FIG. 28, the power supply system, combined with an electronic circuit 181 and a power supply system 182, can be used in a system unit 180. It is to be noted that one example of a power supply circuit diagram of a power supply device is shown in FIG. 29. FIG. 29 shows a power supply circuit of a power supply device configured with a power circuit and a control circuit, the power supply circuit in which a DC voltage is converted into AC by being switched at high frequencies by an inverter 192 (which is configured with MOSFETs A to D) and then electrical insulation and voltage transformation are performed by a transformer 193, rectification is performed by a rectification MOSFET 194 (A to B′) and smoothing is then performed by a DCL 195 (smoothing coils L1 and L2) and a capacitor, and a direct-current voltage is output. At the time of output, the output voltage is compared with a reference voltage by a voltage comparator 197, and the inverter 192 and the rectification MOSFET 194 are controlled by a PWM control circuit 196 so as to obtain a desired output voltage.

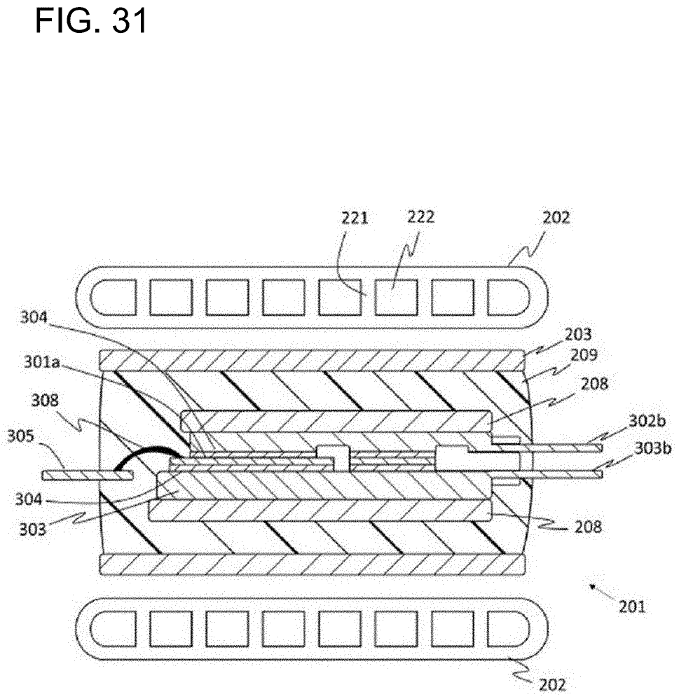

In the present disclosure, the semiconductor device is preferably a power card, more preferably includes a cooler and an insulating member, the cooler being provided on each side of the semiconductor layer with at least the insulating member being placed therebetween, and most preferably has a heat dissipation layer provided on each side of the semiconductor layer and has the cooler provided on the outside of each heat dissipation layer with at least the insulating member being placed therebetween. FIG. 31 shows a power card which is one of suitable embodiments of the present disclosure. The power card of FIG. 31 is a double side cooled power card 201 and includes a coolant tube 202, a spacer 203, an insulating plate (an insulating spacer) 208, a resin encapsulating portion 209, a semiconductor chip 301a, a metal heat-transfer plate (a projecting terminal portion) 302b, a heat sink and electrode 303, a metal heat-transfer plate (a projecting terminal portion) 303b, a solder layer 304, a control electrode terminal 305, and a bonding wire 308. A thickness-direction cross section of the coolant tube 202 has a large number of channels 222 obtained by division by a large number of partitions 221 extending in a channel direction with a predetermined spacing left therebetween. This suitable power card can achieve better heat dissipation and can ensure higher reliability.

The semiconductor chip 301a is bonded on a principal surface inside the metal heat-transfer plate 302b by the solder layer 304 and the metal heat-transfer plate (the projecting terminal portion) 302b is bonded to the remaining principal surface of the semiconductor chip 301a by the solder layer 304, whereby an anode electrode plane and a cathode electrode plane of a flywheel diode are connected to a collector electrode plane and an emitter electrode plane of an IGBT in what is called antiparallel connection. Examples of a material for the metal heat-transfer plates (the projecting terminal portions) 302b and 303b include Mo, W or the like. There is a difference in thickness between the metal heat-transfer plates (the projecting terminal portions) 302b and 303b which absorbs differences in the thickness of the semiconductor chip 301a, which makes the outer surfaces of the metal heat-transfer plates 302b and 303b flat.

The resin encapsulating portion 209 is made of epoxy resin, for example, and covers the side surfaces of these metal heat-transfer plates 302b and 303b by molding and the semiconductor chip 301a is encapsulated in the resin encapsulating portion 209 by molding. It is to be noted that the outer principal surfaces, that is, the contact heat-receiving surfaces of the metal heat-transfer plates 302b and 303b are fully exposed. The metal heat-transfer plates (the projecting terminal portions) 302b and 303b protrude rightward in FIG. 31 from the resin encapsulating portion 209, and the control electrode terminal 305, which is what is called a leadframe terminal, connects a gate (control) electrode plane of the semiconductor chip 301a on which the IGBT, for example, is formed and the control electrode terminal 305.

The insulating plate 208, which is an insulating spacer, is configured with, for example, an aluminum nitride film; the insulating plate 208 may be other insulating films. The insulating plate 208 completely covers the metal heat-transfer plates 302b and 303b and is in intimate contact therewith; the insulating plate 208 and the metal heat-transfer plates 302b and 303b may only be in contact with each other, a good heat transfer material such as silicone grease may be applied, or they may be bonded to each other by various methods. Moreover, an insulating layer may be formed by ceramic spraying or the like, the insulating plate 208 may be bonded on the metal heat-transfer plate, or the insulating plate 208 may be bonded or formed on the coolant tube.

The coolant tube 202 is made by cutting a plate material formed of an aluminum alloy by a pultrusion molding method or an extrusion molding method so as to have a necessary length. A thickness-direction cross section of the coolant tube 202 has a large number of channels 222 obtained by division by a large number of partitions 221 extending in a channel direction with a predetermined spacing left therebetween. The spacer 203 may be for example, a soft metal plate of a solder alloy or the like; the spacer 203 may be a film formed by application or the like on the contact surfaces of the metal heat-transfer plates 302b and 303b. The surface of this soft spacer 203 is easily deformed and conforms to microscopic asperities and warpage of the insulating plate 208 and microscopic asperities and warpage of the coolant tube 202 and thereby reduces thermal resistance. It is to be noted that publicly known highly thermally conductive grease or the like may be applied to the surface or the like of the spacer 203 or the spacer 203 may be omitted.

### EMBODIMENTS

Hereinafter, embodiments of the present disclosure will be described using the drawings; it is to be noted that the present disclosure is not limited to these embodiments.

The multilayer structure can be obtained by forming a crystal growth layer on a crystal growth substrate by crystal growth including lateral crystal growth, adhering a support having a thermal conductivity of 100 W/m·K or higher at ambient temperature to the crystal growth layer, and separating the crystal growth substrate.

### Embodiment

### 1. Fabrication of Stacked Structure

An ELO mask is formed on a front surface as a crystal growth substrate. It is to be noted that a sapphire substrate is used as the crystal growth substrate. In the present disclosure, it is preferable to use a sapphire substrate whose principal plane is an r plane or an S plane as the sapphire substrate. FIG. 1(a) shows a sapphire substrate 1. As shown in FIG. 1(b), an ELO mask 5 having a striped pattern is formed on a crystal growth surface of the sapphire substrate 1. A crystal growth layer of α-Ga₂O₃ is formed by mist CVD using the crystal growth substrate of FIG. 1(b), and a multilayer structure of FIG. 1(c) is obtained. The multilayer structure (c) has a crystal growth layer 8 formed on the sapphire substrate 1 with the ELO mask 5 on a front surface. After the multilayer structure (c) is obtained, a SiC substrate is adhered to the crystal growth layer 8 as a support substrate 10, and a multilayer structure of FIG. 2(d) is obtained. After the multilayer structure (d) is obtained, the sapphire substrate 1 is separated using a mechanical separating means, and a multilayer structure of FIG. 3(e) is obtained. After the multilayer structure (e) is obtained, the ELO mask 5 is removed using CMP, and a multilayer structure of FIG. 4(f) is obtained. After the multilayer structure (f) is obtained, crystal growth is performed again on the crystal growth layer 8 using mist CVD, whereby a regrowth layer 12 is formed and a multilayer structure of FIG. 5(g) is obtained. The multilayer structure (f) or (g) obtained in this way has a large-area crystal film having a favorable film thickness distribution and a film thickness of 30 μm or less and achieves good heat dissipation.

### 2. Evaluations

Stacked structures were fabricated by applying the fabrication example of 1. above to the conditions of Tables 1 and 2 below and performing crystal growth in such a way that a crystal growth layer had a thickness of 10 μm, and an area, a film thickness distribution, and a dislocation density were evaluated.

TABLE 1

| | Substrate | | Crystal | | | Film | |
|---|---|---|---|---|---|---|---|
| | for Crystal | ELO | Growth | | | Thickness | Dislocation |
| | Growth | Mask | Layer | Support | Area | Distribution | Density |
| First | r-plane | Striped | α-Ga₂O₃ | SiC | Excellent | Excellent | Good |
| Embodiment | sapphire | pattern | | substrate | | | |
| | substrate | SiO₂ | | | | | |
| Second | S-plane | Striped | α-Ga₂O₃ | SiC | Excellent | Excellent | Good |
| Embodiment | sapphire | pattern | | substrate | | | |
| | substrate | SiO₂ | | | | | |
| Third | m-plane | Striped | α-Ga₂O₃ | SiC | Good | Good | Good |
| Embodiment | sapphire | pattern | | substrate | | | |
| | substrate | SiO₂ | | | | | |
| First | r-plane | Striped | α-Ga₂O₃ | None | Not good | Not good | Good |
| Comparative | sapphire | pattern | | | | | |
| Example | substrate | SiO₂ | | | | | |
| Second | S-plane | Striped | α-Ga₂O₃ | None | Not good | Not good | Good |
| Comparative | sapphire | pattern | | | | | |
| Example | substrate | SiO₂ | | | | | |
| Third | r-plane | None | α-Ga₂O₃ | SiC | Not good | Not good | Not good |
| Comparative | sapphire | | | substrate | | | |
| Example | substrate | | | | | | |

* “Excellent” for an area of 100 cm² or more, “Good” for an area of 15 cm² or more, and “Not good” for an area of less than 15 cm².
* “Very good” for a film thickness distribution of 5% or less, “Good” for a film thickness distribution of 10% or less, and “Not good” for a film thickness distribution of more than 10%.
* “Good” for a dislocation density of 1.0 × 10⁶/cm² or less and “Not good” for a dislocation density of more than 1.0 × 10⁶/cm².

TABLE 2

| | Substrate | | Crystal | | | Film | |
|---|---|---|---|---|---|---|---|
| | for Crystal | ELO | Growth | | | Thickness | Dislocation |
| | Growth | Mask | Layer | Support | Area | Distribution | Density |
| Fourth | (100)-plane | Striped | β-Ga₂O₃ | SiC | Excellent | Excellent | Good |
| Embodiment | β-Ga₂O₃ | pattern | | substrate | | | |
| | substrate | SiO₂ | | | | | |
| Fifth | (001)-plane | Striped | β-Ga₂O₃ | SiC | Excellent | Excellent | Good |
| Embodiment | β-Ga₂O₃ | pattern | | substrate | | | |
| | substrate | SiO₂ | | | | | |
| Fourth | (100)-plane | Striped | β-Ga₂O₃ | None | Not good | Not good | Good |
| Comparative | β-Ga₂O₃ | pattern | | | | | |
| Example | substrate | SiO₂ | | | | | |
| Fifth | (001)-plane | Striped | β-Ga₂O₃ | None | Not good | Not good | Good |
| Comparative | β-Ga₂O₃ | pattern | | | | | |
| Example | substrate | SiO₂ | | | | | |
| Sixth | (100)-plane | None | β-Ga₂O₃ | SiC | Not good | Not good | Good |
| Comparative | β-Ga₂O₃ | | | substrate | | | |
| Example | substrate | | | | | | |

* “Excellent” for an area of 100 cm² or more, “Good” for an area of 15 cm² or more, and “Not good” for an area of less than 15 cm².
* “Very good” for a film thickness distribution of 5% or less, “Good” for a film thickness distribution of 10% or less, and “Not good” for a film thickness distribution of more than 10%.
* “Good” for a dislocation density of 1.0 × 10³/cm² or less and “Not good” for a dislocation density of more than 1.0 × 10³/cm².

As is clear from Tables 1 and 2, the multilayer structure of the present disclosure has a large-area crystal film having a favorable film thickness distribution and a film thickness of 30 μm or less and achieves good heat dissipation.

The multilayer structure of the present disclosure can be used in all the fields such as semiconductors (for example, a compound semiconductor electronic device), electronic parts, electrical apparatus parts, optical and electronic photograph-related equipment, and industrial components, and is particularly useful for semiconductor devices and so forth.

The embodiments of the present invention are exemplified in all respects, and the scope of the present invention includes all modifications within the meaning and scope equivalent to the scope of claims.

### REFERENCE SIGNS LIST

a interval
1 substrate (sapphire substrate)
1a front surface of a substrate (crystal growth surface)
2a projections
2b depressions
3 crystal growth layer (epitaxial layer)
3a buffer layer
4 mask layer
5 mask (on a substrate)
6 opening of a mask
7 mask (on a first lateral crystal growth layer)
8 crystal growth layer (first lateral crystal growth layer)
9 second lateral crystal growth layer
10 support (support substrate)
11 support (support substrate)
12 regrowth layer
15 second mask
19 mist CVD equipment
20 sample-to-be-subjected-to-film-formation
21 sample stage
22a carrier gas source
22b carrier gas (dilute) source
23a flow control valve
23b flow control valve
24 mist generation source
24a raw material solution
24b mist
25 container
25a water
26 ultrasonic vibrator
27 film formation chamber
28 heater
50 halide vapor phase epitaxy (HVPE) system
51 reaction chamber
52a heater
52b heater
53a halogen-containing source gas supply source
53b metal-containing source gas supply pipe
54a reactive gas supply source
54b reactive gas supply pipe
55a oxygen-containing source gas supply source
55b oxygen-containing source gas supply pipe
56 substrate holder
57 metal source
58 protective sheet
59 gas exhaust portion
170 power supply system
171 power supply device
172 power supply device
173 control circuit
180 system unit
181 electronic circuit
182 power supply system
192 inverter
193 transformer
194 rectification MOSFET
195 DCL
196 PWM control circuit
197 voltage comparator
201 double side cooled power card
202 coolant tube
203 spacer
208 insulating plate (insulating spacer)
209 resin encapsulating portion
221 partition
222 channel
301a semiconductor chip
302b metal heat-transfer plate (projecting terminal portion)
303 heat sink and electrode
303b metal heat-transfer plate (projecting terminal portion)
304 solder layer
305 control electrode terminal
308 bonding wire
500 semiconductor element
501 solder
502 leadframe, circuit board, or heat dissipation substrate

What is claimed is:

1. A multilayer structure comprising:
a crystal film containing a crystalline metal oxide as a major component and arranged directly on a support or arranged on the support via another layer, the support having a thermal conductivity of 100 W/m·K or higher at ambient temperature, the crystal film having a corundum structure, a film thickness of in a range of 1 μm to 30 μm, and an area of 15 cm² or more, a distribution of the film thickness in the area falling within a range of ±10%.

2. A multilayer structure comprising:
a crystal film containing a crystalline metal oxide as a major component and arranged directly on a support or arranged on the support via another layer, the support having a thermal conductivity of 100 W/m·K or higher at ambient temperature, the crystal film having a β gallia structure, a principal plane of the crystal film being a (001) plane or a (100) plane, the crystal film having a film thickness of in a range of 1 μm to 30 μm and an area of 15 cm′ or more, a distribution of the film thickness in the area falling within a range of ±10%.

3. The multilayer structure according to claim 1,
wherein the crystalline metal oxide contains at least gallium.

4. The multilayer structure according to claim 1,
wherein the crystal film is a semiconductor film.

5. The multilayer structure according to claim 1,
wherein a principal plane of the crystal film is an r plane or an S plane.

6. The multilayer structure according to claim 1,
wherein the distribution of the film thickness in the area falls within a range of ±5%.

7. The multilayer structure according to claim 1,
wherein a dislocation density of the crystal film is 1.0×10⁶/cm² or less.

8. The multilayer structure according to claim 2,
wherein a dislocation density of the crystal film is 1.0×10³/cm² or less.

9. The multilayer structure according to claim 1,
wherein the area of the crystal film is 100 cm² or more.

10. The multilayer structure according to claim 1,
wherein the support contains silicon.

11. A semiconductor device comprising at least:
an electrode; and
a semiconductor layer,
wherein the semiconductor device includes the multilayer structure according to claim 1.

12. The semiconductor device according to claim 13,
wherein the crystal film of the multilayer structure is a semiconductor film, and
wherein the semiconductor film is used as the semiconductor layer.

13. The semiconductor device according to claim 13,
wherein the semiconductor device is a power device.

14. A semiconductor system comprising:
a semiconductor device,
wherein the semiconductor device is the semiconductor device according to claim 1.

15. A method of producing a multilayer structure comprising:
forming a crystal growth layer on a crystal growth substrate by crystal growth including lateral crystal growth;
adhering a support having a thermal conductivity of 100 W/m·K or higher at ambient temperature to the crystal growth layer; and
separating the crystal growth substrate.

16. The production method according to claim 15,
wherein the support contains silicon.

17. The production method according to claim 15,
wherein an area of the support is 15 cm² or more.

18. The production method according to claim 15,
wherein the crystal growth layer contains gallium.

19. The production method according to claim 15
wherein the crystal growth layer contains a crystalline oxide as a major component.

20. The production method according to claim 17,
wherein the crystal growth substrate has a corundum structure, and
wherein a crystal growth surface of the crystal growth substrate is an r plane or an S plane.

21. The production method according to claim 17,
wherein the crystal growth substrate has a β gallia structure, and
wherein a crystal growth surface of the crystal growth substrate is a (100) plane or a (001) plane.
